(19) United States
(12) Patent Application Publication
(10) Pub. No.: US 2018/0269226 A1
(43) Pub. Date: Sep. 20, 2018

(54) SEMICONDUCTOR MEMORY DEVICE AND METHOD FOR MANUFACTURING SAME

(71) Applicant: Toshiba Memory Corporation, Minato-ku (JP)

(72) Inventors: Takeshi Sonehara, Yokkaichi (JP); Shigehiro Yamakita, Yokkaichi (JP); Takeshi Sakaguchi, Yokkaichi (JP); Ken Komiya, Nagoya (JP); Katsuyuki Kitamoto, Yokkaichi (JP); Tomohiro Yamada, Yokkaichi (JP); Ryota Fujitsuka, Yokkaichi (JP); Nobuhito Kuge, Yokkaichi (JP)

(73) Assignee: Toshiba Memory Corporation, Minato-ku (JP)

(21) Appl. No.: 15/918,072

(22) Filed: Mar. 12, 2018

Related U.S. Application Data
(60) Provisional application No. 62/472,120, filed on Mar. 16, 2017.

(51) Int. Cl. H01L 27/11582; H01L 27/11575

(52) U.S. Cl. CPC H01L 27/11582; H01L 27/11565; H01L 27/11575

(57) ABSTRACT

A semiconductor memory device includes a substrate, a first stacked body provided in a first region on the substrate, a transistor formed in a second region of the substrate, and a block member provided between the first stacked body and the transistor. The first stacked body includes a plurality of first silicon oxide films and a plurality of electrode films stacked alternately one by one. Diffusion coefficient of hydrogen in the block member is lower than diffusion coefficient of hydrogen in silicon oxide.

### CROSS-REFERENCE TO RELATED APPLICATIONS

This application is based upon and claims the benefit of priority from U.S. Provisional Patent Application 62/472,120, filed on Mar. 16, 2017; the entire contents of which are incorporated herein by reference.

### FIELD

Embodiments relate to a semiconductor memory device and a method for manufacturing the same.

### BACKGROUND

In recent years, there has been proposed a stacked semiconductor memory device in which memory cells are integrated three-dimensionally. Such a stacked semiconductor memory device is provided with a stacked body on a semiconductor substrate. The stacked body includes electrode films and insulating films alternately stacked therein. Semiconductor pillars are provided through the stacked body. A memory cell is formed for each intersecting portion of the electrode film and the semiconductor pillar. In such a semiconductor memory device, the problem is to ensure reliability.

### BRIEF DESCRIPTION OF THE DRAWINGS

FIGS. 1 to 5 are sectional views showing a method for manufacturing a semiconductor memory device according to a first embodiment;

FIGS. 6 to 8 are sectional views showing the semiconductor memory device according to the first embodiment;

FIGS. 9A to 9C are sectional views showing a method for manufacturing a semiconductor memory device according to a second embodiment;

FIG. 10 is a sectional view showing the semiconductor memory device according to the second embodiment;

FIGS. 11A and 11B are sectional views showing a method for manufacturing a semiconductor memory device according to a third embodiment;

FIG. 12 is a sectional view showing the semiconductor memory device according to the third embodiment;

FIG. 13 is a sectional view showing a method for manufacturing a semiconductor memory device according to a fourth embodiment;

FIG. 14 is a sectional view showing the semiconductor memory device according to the fourth embodiment;

FIGS. 15A and 15B are sectional views showing a method for manufacturing a semiconductor memory device according to a fifth embodiment;

FIG. 16 is a sectional view showing the semiconductor memory device according to the fifth embodiment;

FIG. 17 is a sectional view showing a method for manufacturing a semiconductor memory device according to a sixth embodiment;

FIG. 18 is a sectional view showing a method for manufacturing a semiconductor memory device according to a seventh embodiment;

FIG. 19 is a plan view showing a semiconductor memory device according to an eighth embodiment;

FIG. 20 is a sectional view showing the semiconductor memory device according to the eighth embodiment;

FIG. 21 is a sectional view showing a semiconductor memory device according to a ninth embodiment;

FIG. 22 is a sectional view showing a semiconductor memory device according to a tenth embodiment;

FIG. 23 is a sectional view showing a semiconductor memory device according to an eleventh embodiment;

FIGS. 24 to 26 are sectional views showing a method for manufacturing a semiconductor memory device according to a twelfth embodiment;

FIG. 27 is a sectional view showing the semiconductor memory device according to the twelfth embodiment;

FIG. 28 is a sectional view showing a semiconductor memory device according to a thirteenth embodiment;

FIG. 29 is a sectional view showing a semiconductor memory device according to a fourteenth embodiment;

FIG. 30 is a plan view showing an alumina member of the semiconductor memory device according to the fourteenth embodiment;

FIG. 31 is a plan view showing an alumina member of a semiconductor memory device according to a fifteenth embodiment; and

FIGS. 32 and 33 are sectional views showing a method for manufacturing a semiconductor memory device according to a sixteenth embodiment.

### DETAILED DESCRIPTION

A semiconductor memory device according to one embodiment includes a substrate, a first stacked body provided in a first region on the substrate, a transistor formed in a second region of the substrate, and a block member provided between the first stacked body and the transistor. The first stacked body includes a plurality of first silicon oxide films and a plurality of electrode films stacked alternately one by one. Diffusion coefficient of hydrogen in the block member is lower than diffusion coefficient of hydrogen in silicon oxide.

### First Embodiment

First, a method for manufacturing a semiconductor memory device according to this embodiment is described.

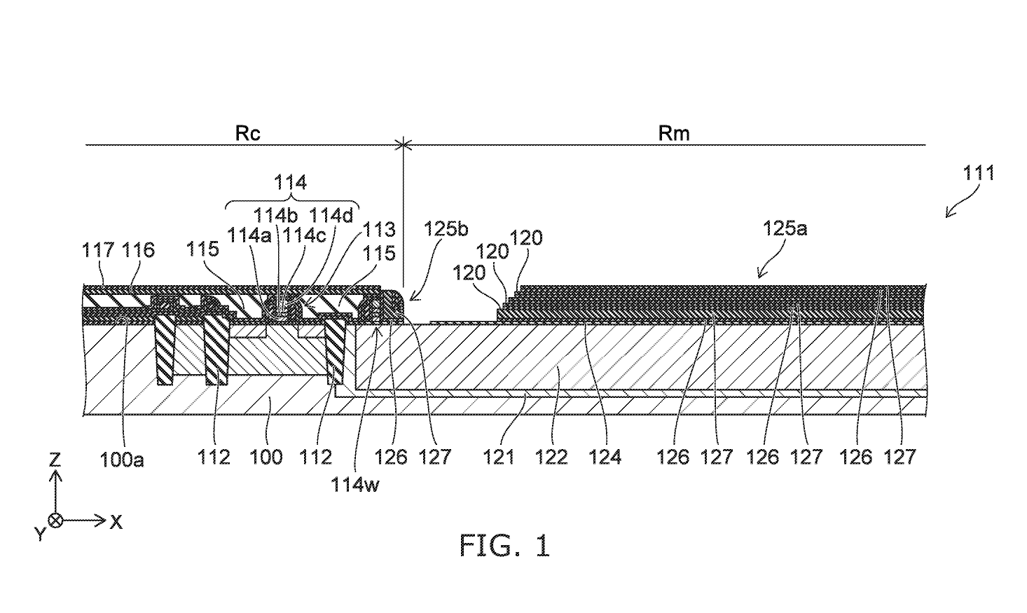

FIGS. 1 to 5 are sectional views showing a method for manufacturing a semiconductor memory device according to this embodiment.

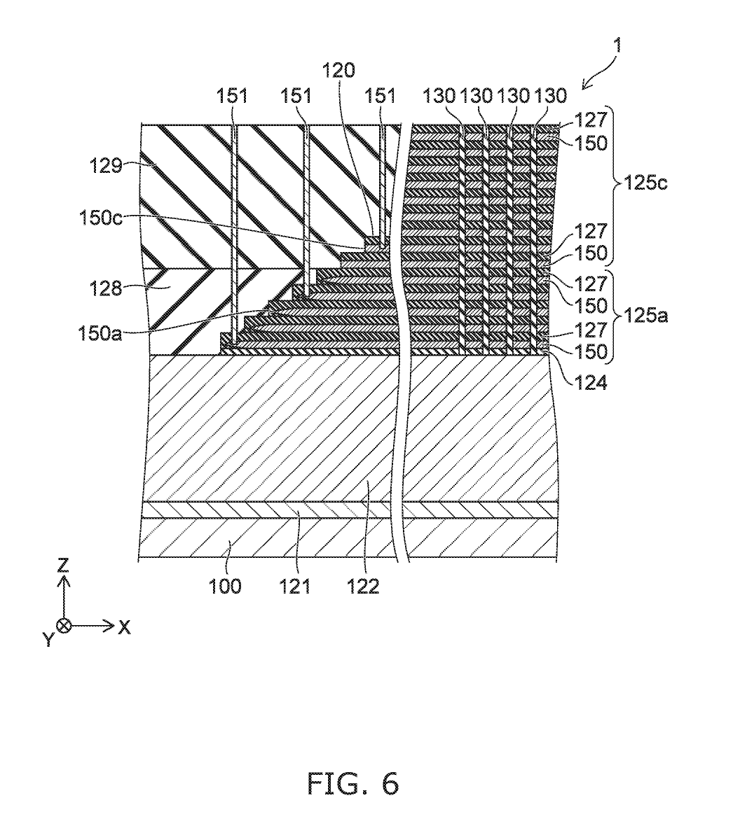

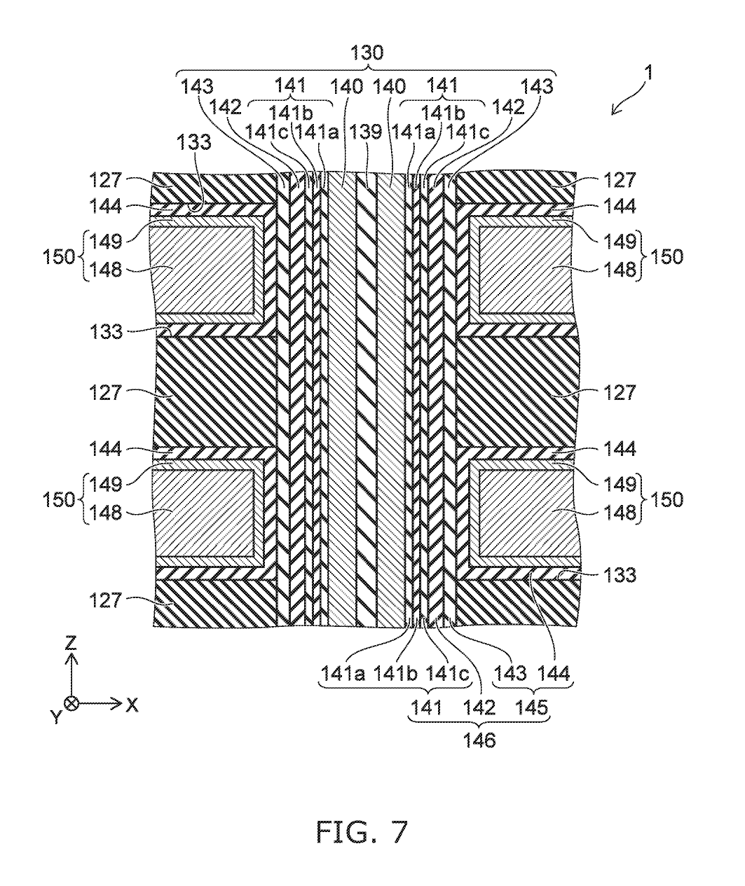

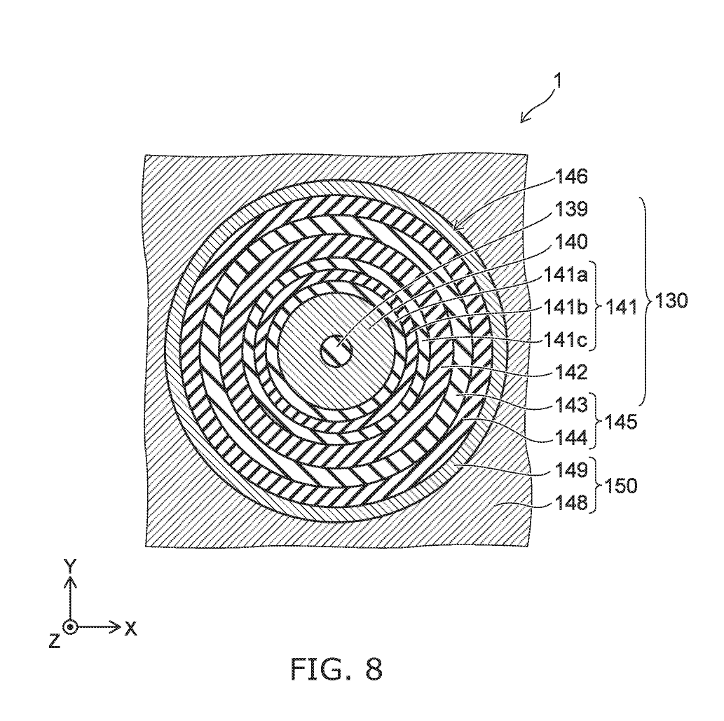

FIGS. 6 to 8 are sectional views showing the semiconductor memory device according to this embodiment.

First, as shown in FIG. 1, a silicon substrate 100 is prepared. In this specification, an XYZ orthogonal coordinate system is hereinafter adopted for convenience of description. Two directions parallel to the upper surface 100a of the silicon substrate 100 and orthogonal to each other are referred to as “X-direction” and “Y-direction”. The direction perpendicular to the upper surface 100a is referred to as “Z-direction”. The silicon substrate 100 is formed from e.g. a single crystal of silicon (Si).

Then, the silicon substrate 100 is used to fabricate an intermediate structural body 111. A memory cell region Rm and a peripheral circuit region Rc are defined in the intermediate structural body 111. The peripheral circuit region Rc is placed around the memory cell region Rm.

In the peripheral circuit region Rc, an upper layer portion of the silicon substrate 100 is partitioned by STI 112. A field effect transistor 113 is formed on and above the portion of the silicon substrate 100 partitioned by the STI 112. The gate electrode 114 of the transistor 113 includes a polysilicon layer (Si layer) 114a, a tungsten silicide nitride layer (WSiN layer) 114b, a tungsten nitride layer (WN layer) 114c, and a tungsten layer (W layer) 114d stacked in this order from the silicon substrate 100 side. A silicon oxide film 115 is buried between the gate electrodes 114. A silicon nitride film 116 is provided above the gate electrode 114 and the silicon oxide film 115. A silicon oxide film 117 is provided on the silicon nitride film 116.

In the memory cell region Rm, an n-type well 121 is formed in an upper layer portion of the silicon substrate 100. A p-type well 122 is formed in an upper layer portion of the n-type well 121. A silicon oxide film 124 is provided on the silicon substrate 100. A stacked body 125a is provided on the silicon oxide film 124. In the stacked body 125a, silicon nitride films 126 and silicon oxide films 127 are stacked alternately along the Z-direction. The end part of the stacked body 125a is shaped like a staircase in which a terrace 120 is formed for each silicon nitride film 126.

A stacked body 125b is provided in the end part on the memory cell region Rm side of the peripheral circuit region Rc. The stacked body 125b is provided on the upper surface of the p-type well 122 and on the side surface of the gate electrode structural body 114w. The gate electrode structural body 114w has the same configuration as the gate electrode 114 of the transistor 113. However, the gate electrode structural body 114w is a dummy structural body that does not constitute a transistor and does not function electrically. Also in the stacked body 125b, silicon nitride films 126 and silicon oxide films 127 are stacked alternately. However, the films are bent generally at a right angle. The stacking direction lies in the Z-direction and the X-direction.

The stacked bodies 125a and 125b are formed as follows. Silicon nitride films 126 and silicon oxide films 127 are formed alternately by the CVD (chemical vapor deposition) method using a raw material gas containing silicon and hydrogen such as silane (SiH₄). Thus, a stacked film is formed on the entire surface of the silicon substrate 100. Then, this stacked film is selectively removed, and the end part is processed in a staircase shape. Thus, the stacked bodies 125a and 125b are formed. At this time, hydrogen originating from the raw material gas of CVD is contained in the stacked body 125a and the stacked body 125b.

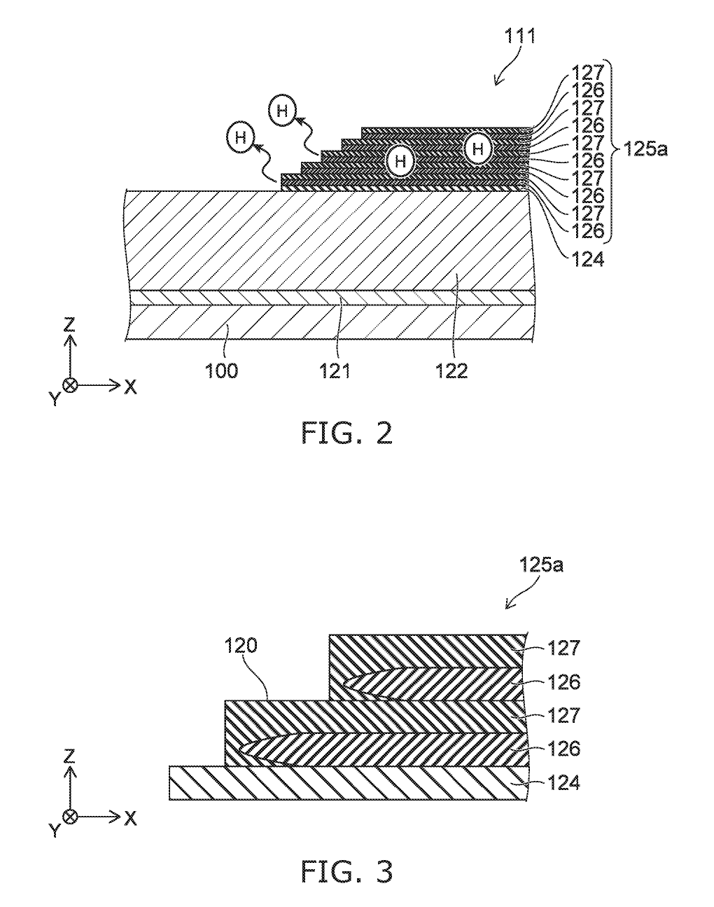

Next, as shown in FIG. 2, the intermediate structural body 111 is heated in an oxidizing atmosphere. Thus, hydrogen gas is eliminated from the stacked bodies 125a and 125b into the environment. In FIG. 2, hydrogen is schematically denoted by an encircled symbol of letter “H”. This also similarly applies to the other figures described later.

At this time, as shown in FIG. 3, the end part of the silicon nitride film 126 is oxidized from the interface between the silicon nitride film 126 and the silicon oxide film 127 and turned to silicon oxide. Thus, the end part of the silicon nitride film 126 is shaped like a bird's beak and narrowed toward the tip.

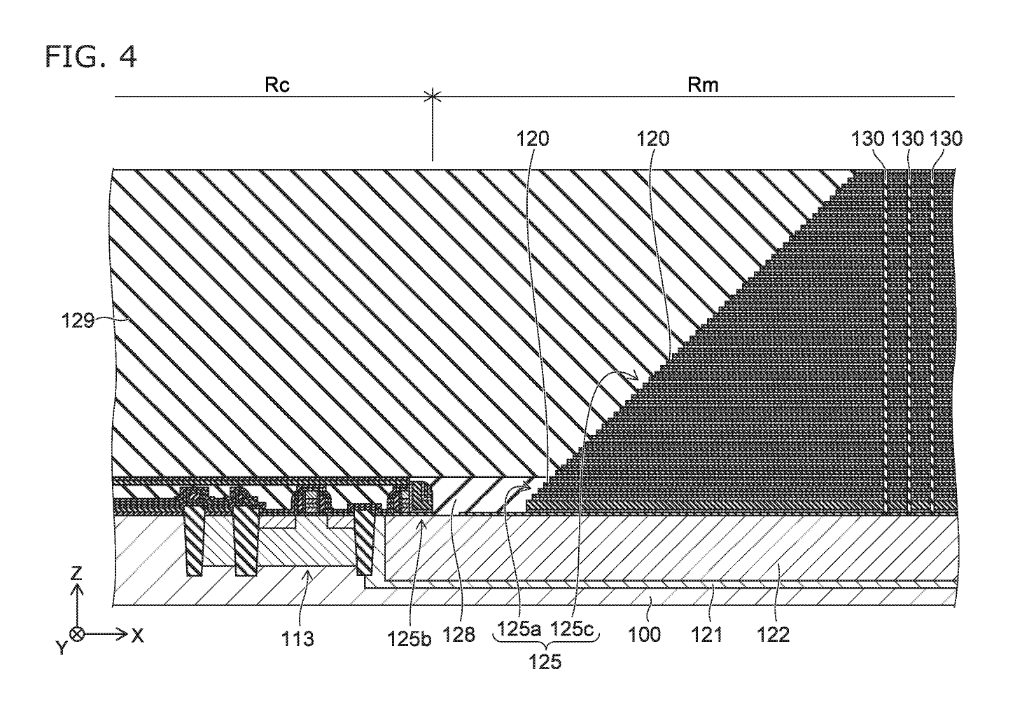

Next, as shown in FIG. 4, a silicon oxide film 128 is buried between the stacked body 125a and the stacked body 125b. Next, silicon nitride films 126 and silicon oxide films 127 are alternately stacked to form a stacked film on the entire surface of the silicon substrate 100. Then, the end part of this stacked film is processed in a staircase shape. Thus, a stacked body 125c is formed on the stacked body 125a. The stacked body 125a and the stacked body 125c are formed continuously to constitute one stacked body. The end part thereof is shaped like a continuous staircase. In the following, the stacked body 125a and the stacked body 125c are also generally referred to as stacked body 125.

Next, an interlayer insulating film 129 made of e.g. silicon oxide is formed so as to cover the stacked body 125c. The interlayer insulating film 129 is formed in both the memory cell region Rm and the peripheral circuit region Rc.

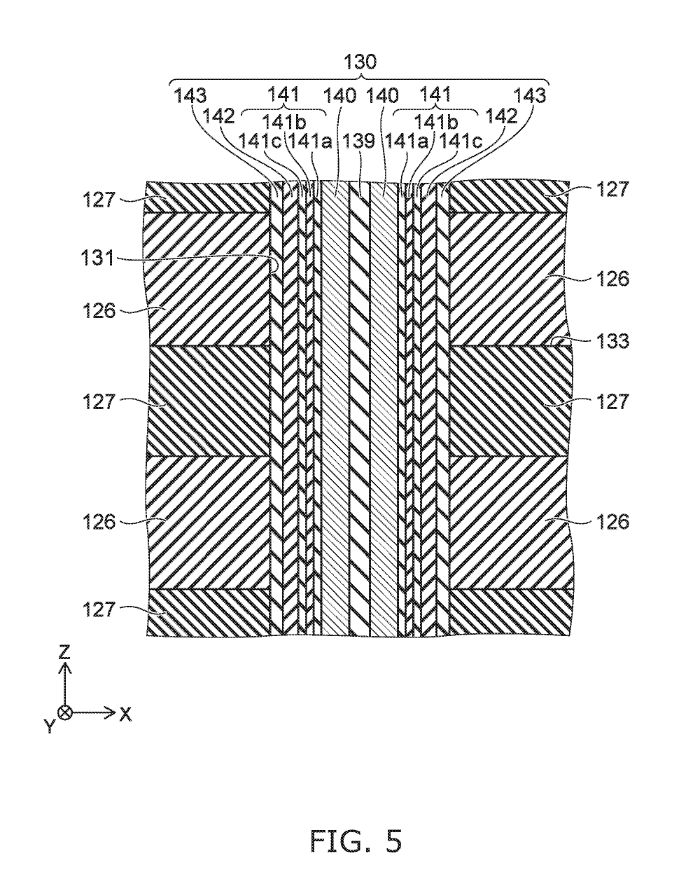

Next, as shown in FIGS. 4 and 5, a columnar member 130 is formed in the stacked body 125. Specifically, a memory hole 131 is formed in the stacked body 125 by the lithography method and the RIE (reactive ion etching) method. The memory hole 131 is shaped like a generally circular cylinder extending in the Z-direction. The silicon substrate 100 is exposed at the bottom surface of the memory hole 131.

Next, a silicon oxide layer 143 is formed on the inner surface of the memory hole 131. Next, a charge storage film 142 is formed by depositing silicon nitride. The charge storage film 142 is a film capable of storing charge. The charge storage film 142 is made of e.g. a material containing electron trap sites. In this embodiment, the charge storage film 142 is made of silicon nitride.

Next, silicon oxide, silicon nitride, and silicon oxide are deposited in this order to form a silicon oxide layer 141c, a silicon nitride layer 141b, and a silicon oxide layer 141a. The silicon oxide layer 141c, the silicon nitride layer 141b, and the silicon oxide layer 141a constitute a tunnel insulating film 141. The tunnel insulating film 141 is a film that is normally insulating, but passes a tunnel current under application of a prescribed voltage within the range of the driving voltage of the semiconductor memory device.

Next, a cover silicon layer (not shown) is formed by depositing silicon. Then, RIE is performed to remove the cover silicon layer, the tunnel insulating film 141, the charge storage film 142, and the silicon oxide layer 143. Next, a body silicon layer (not shown) is formed by depositing silicon. The body silicon layer is connected to the silicon substrate 100. The cover silicon layer and the body silicon layer form a silicon pillar 140. Next, a core member 139 is formed by depositing silicon oxide. The core member 139 is buried in the memory hole 131. Thus, the columnar member 130 is formed.

Next, as shown in FIGS. 6 to 8, a slit (not shown) is formed in the stacked body 125 and the interlayer insulating film 129. The slit extends along the XZ plane and penetrates through the stacked body 125 in the X-direction and the Z-direction. However, the slit does not reach the stacked body 125b.

Next, the silicon nitride film 126 (see FIG. 5) is removed through the slit by e.g. wet etching with hot phosphoric acid. At this time, the silicon oxide film 127 and the columnar member 130 are not substantially removed, and the columnar member 130 supports the silicon oxide film 127. Thus, a space 133 is formed between the silicon oxide films 127.

Next, aluminum oxide is deposited through the slit to form an aluminum oxide layer 144 on the inner surface of the space 133. The silicon oxide layer 143 and the aluminum oxide layer 144 constitute a block insulating film 145. The block insulating film 145 is a film passing substantially no current even under application of voltage within the range of the driving voltage of the semiconductor memory device. The tunnel insulating film 141, the charge storage film 142, and the block insulating film 145 form a memory film 146.

Next, titanium nitride and titanium are deposited through the slit to form a barrier metal layer 149 on the aluminum oxide layer 144. Next, tungsten is deposited in the space 133 through the slit by e.g. the CVD method to form a body part 148. The body part 148 and the barrier metal layer 149 form an electrode film 150. Next, etching is performed to remove tungsten, titanium, titanium nitride, and aluminum oxide from inside the slit, leaving them only in the space 133. Thus, the electrode film 150 is formed for each space 133. Accordingly, the silicon nitride film 126 is replaced by the electrode film 150 in the stacked bodies 125a and 125c.

At this time, the shape of the electrode film 150 reflects the shape of the silicon nitride film 126. Thus, in the stacked body 125a, the end part of the electrode film 150 is shaped like a bird's beak. On the other hand, in the stacked body 125c, the end part of the electrode film 150 is not shaped like a bird's beak, but the electrode film 150 has a generally equal thickness to the tip. In the stacked body 125b, the silicon nitride film 126 is not replaced by the electrode film 150, but remains as the silicon nitride film 126.

Next, silicon oxide is deposited to form an insulating member (not shown) in the slit. A contact 151 is formed in the interlayer insulating film 129. The lower end of the contact 151 is connected to the end part of the electrode film 150 on the terrace 120. Thus, the semiconductor memory device 1 according to this embodiment is manufactured.

As described above, in the semiconductor memory device 1 according to this embodiment, in the stacked body 125a, the end part of the electrode film 150 is shaped like a bird's beak and continuously thinned toward the tip. In the stacked body 125c, the end part of the electrode film 150 is not shaped like a bird's beak, but has a generally equal thickness to the tip. Thus, the curvature of the tip 150a of the electrode film 150 placed in the stacked body 125a is larger than the curvature of the tip 150c of the electrode film 150 placed in the stacked body 125c. For instance, the curvature of the tip 150c of the lowermost electrode film 150 of the stacked body 125 is larger than the curvature of the tip 150c of the uppermost electrode film 150 of the stacked body 125. On the other hand, in the stacked body 125b, the silicon nitride film 126 is not replaced by the electrode film 150, but remains as the silicon nitride film 126. That is, in the stacked body 125b, the silicon nitride films 126 and the silicon oxide films 127 are stacked alternately.

Next, the effect of this embodiment is described.

In this embodiment, in the step shown in FIG. 2, the intermediate structural body 111 is heated in an oxidizing atmosphere to eliminate hydrogen from the stacked body 125a and the stacked body 125b. This can suppress that hydrogen emitted from the stacked bodies 125a and 125b in the subsequent manufacturing process and the operation of the completed semiconductor memory device 1 intrudes into the peripheral circuit region Rc and damages the structural body of the peripheral circuit region Rc.

For instance, this embodiment can suppress that the tungsten silicide nitride layer (WSiN layer) 114b of the gate electrode 114 of the transistor 113 is reduced by hydrogen and turned to a tungsten silicide layer (WSi layer), which then sucks silicon from the polysilicon layer 114a and reacts therewith to form a gap between the polysilicon layer 114a and the tungsten silicide layer. This embodiment can suppress that impurities such as boron contained in the channel region of the transistor 113 are deactivated by hydrogen to result in variation of the threshold of the transistor 113.

### Second Embodiment

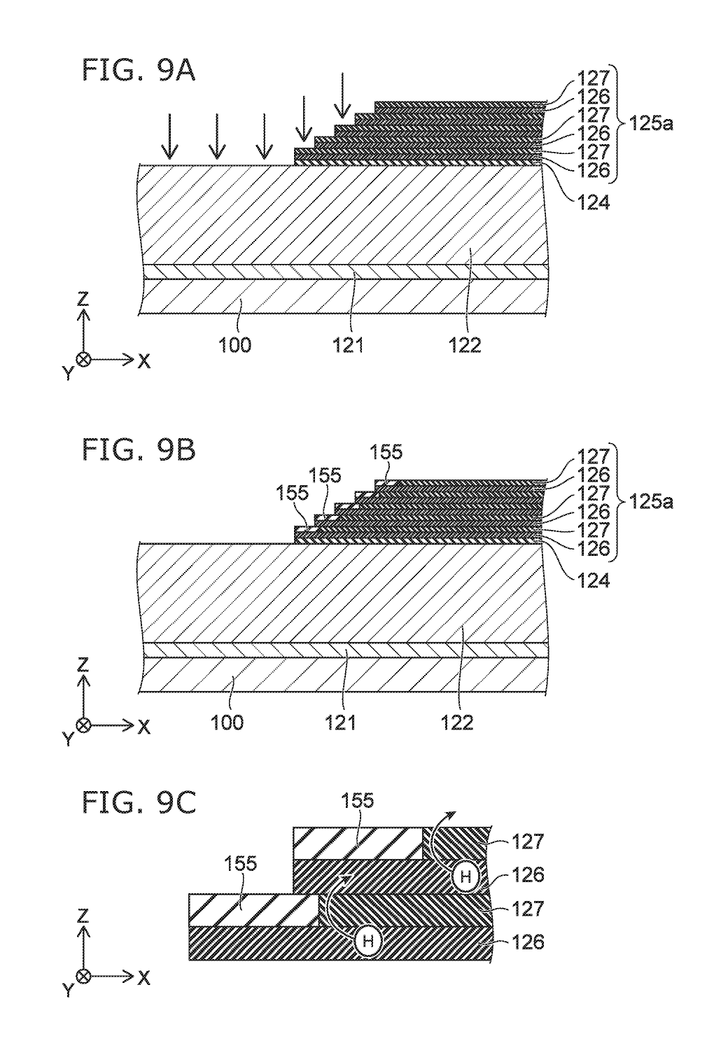

FIGS. 9A to 9C are sectional views showing a method for manufacturing a semiconductor memory device according to this embodiment.

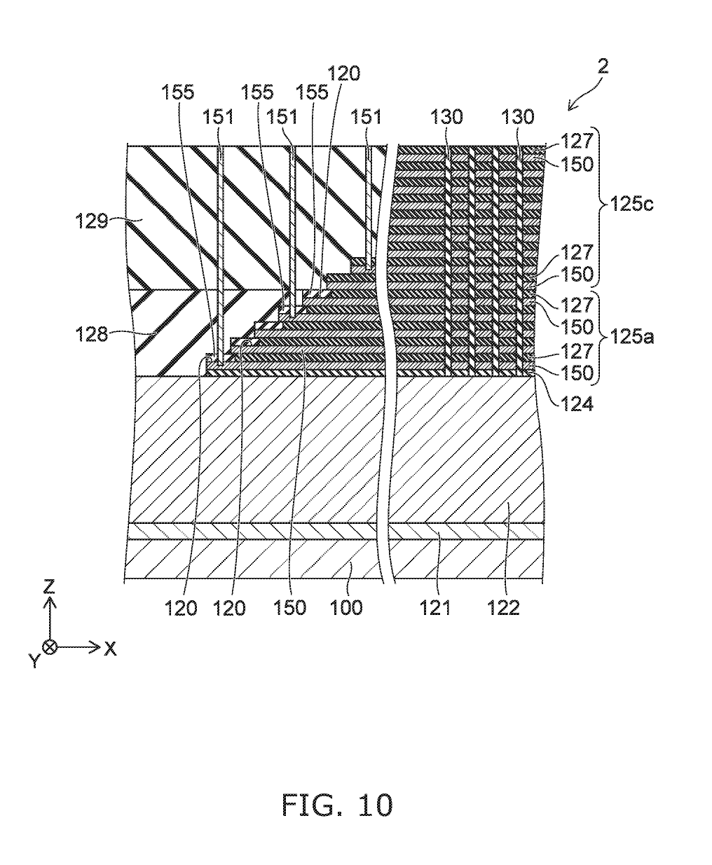

FIG. 10 is a sectional view showing the semiconductor memory device according to this embodiment.

As shown in FIG. 9A, by a method similar to the above first embodiment, silicon nitride films 126 and silicon oxide films 127 are alternately formed by the CVD method to form a stacked body on a silicon substrate 100. The end part of the stacked body is processed in a staircase shape to form a stacked body 125a. At this time, a stacked body 125b is also formed inevitably.

Next, the stacked body 125a is ion-implanted with nitrogen. Thus, as shown in FIG. 9B, the exposed portion of the silicon oxide film 127 is altered to silicon oxynitride and constitutes a block member 155. Instead of ion implantation with nitrogen, the stacked body 125a may be heated in a nitrogen atmosphere.

As a result, as shown in FIG. 9C, migration of hydrogen contained in the stacked body 125a is blocked by the block member 155. Thus, the hydrogen is emitted upward without moving toward the peripheral circuit region Rc. This can suppress that hydrogen emitted from the stacked body 125a intrudes into the peripheral circuit region Rc and damages e.g. the gate electrode 114 of the transistor 113.

Next, a process similar to the above first embodiment is performed. Thus, the semiconductor memory device 2 according to this embodiment is manufactured.

As shown in FIG. 10, in the semiconductor memory device 2, the block member 155 made of silicon oxynitride is provided on the terrace 120 of the electrode film 150 of the stacked body 125a. The upper surface of the silicon oxide film 127 is covered with the electrode film 150. The tip surface of the silicon oxide film 127 directed to the peripheral circuit region Rc is covered with the block member 155. On the other hand, the block member 155 is not provided on the stacked body 125c.

According to this embodiment, the block member 155 thus provided can suppress that hydrogen introduced into the stacked body 125a in the CVD process intrudes into the peripheral circuit region Rc. This can avoid damage to e.g. the gate electrode 114.

The manufacturing method, configuration, and effect of this embodiment other than the foregoing are similar to those of the above first embodiment.

In the step shown in FIG. 9A, instead of nitridation processing, it is also possible to perform ion implantation with impurities such as phosphorus or boron. In this case, the block member 155 is formed from impurity-containing silicon oxide such as PSG (phosphorus silicate glass), BSG (boron silicate glass), or BPSG (boron phosphorus silicate glass).

### Third Embodiment

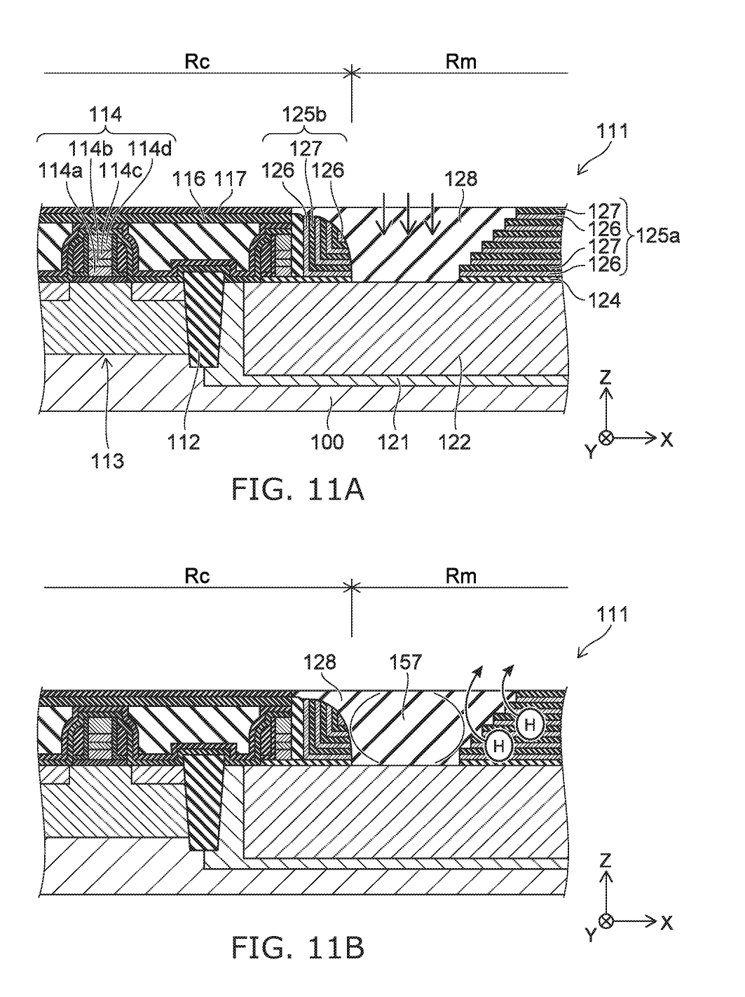

FIGS. 11A and 11B are sectional views showing a method for manufacturing a semiconductor memory device according to this embodiment.

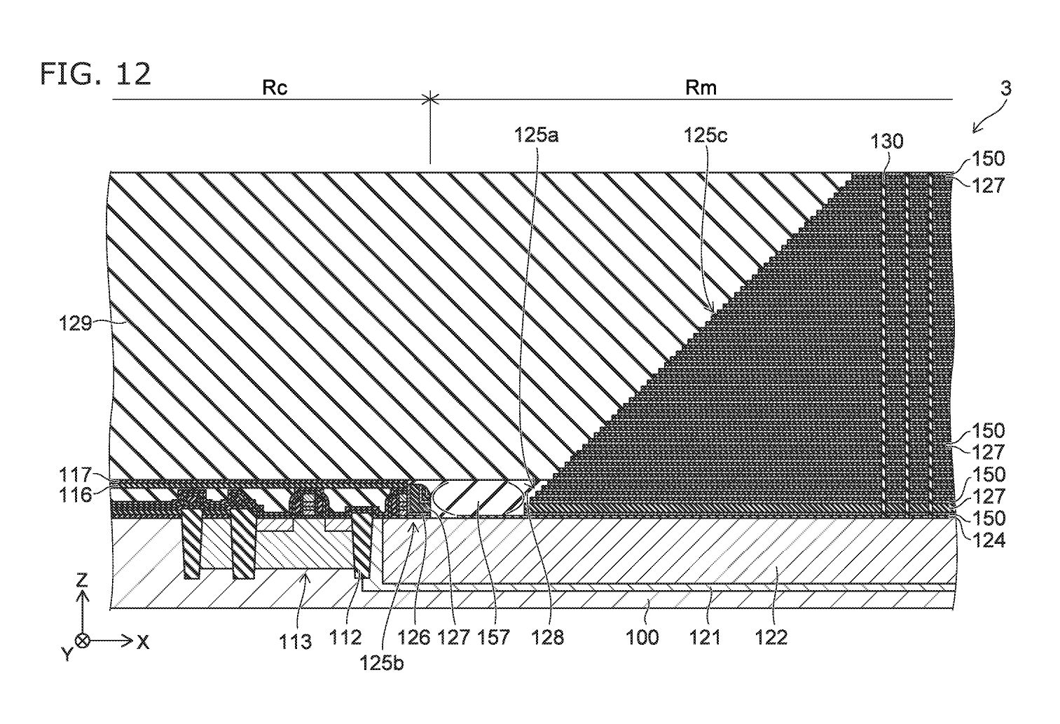

FIG. 12 is a sectional view showing the semiconductor memory device according to this embodiment.

First, an intermediate structural body 111 shown in FIG. is fabricated. In this embodiment, the intermediate structural body 111 is not subsequently heated in an oxidizing atmosphere. However, the intermediate structural body 111 may be heated.

Next, as shown in FIG. 11A, a silicon oxide film 128 is buried between the stacked body 125a and the stacked body 125b. Next, the silicon oxide film 128 is ion-implanted with impurities such as phosphorus, arsenic, or boron, or nitrogen. Thus, at least part of the silicon oxide film 128 is altered to a block member 157. Accordingly, the block member 157 is placed in the silicon oxide film 128. The block member 157 contains PSG, BSG, or BPSG, or silicon oxynitride.

Thus, as shown in FIG. 11B, intrusion of hydrogen emitted from the stacked body 125a into the peripheral circuit region Rc is blocked by the block member 157, and the hydrogen is emitted upward. This can suppress damage to the peripheral circuit region Rc due to hydrogen and avoid breakage of e.g. the gate electrode 114.

Next, a process similar to the above first embodiment is performed. Thus, as shown in FIG. 12, the semiconductor memory device 3 according to this embodiment is manufactured.

In the semiconductor memory device 3, the silicon oxide film 128 is buried between the stacked body 125a and the stacked body 125b. The block member 157 is provided in the silicon oxide film 128.

The manufacturing method, configuration, and effect of this embodiment other than the foregoing are similar to those of the above first embodiment.

### Fourth Embodiment

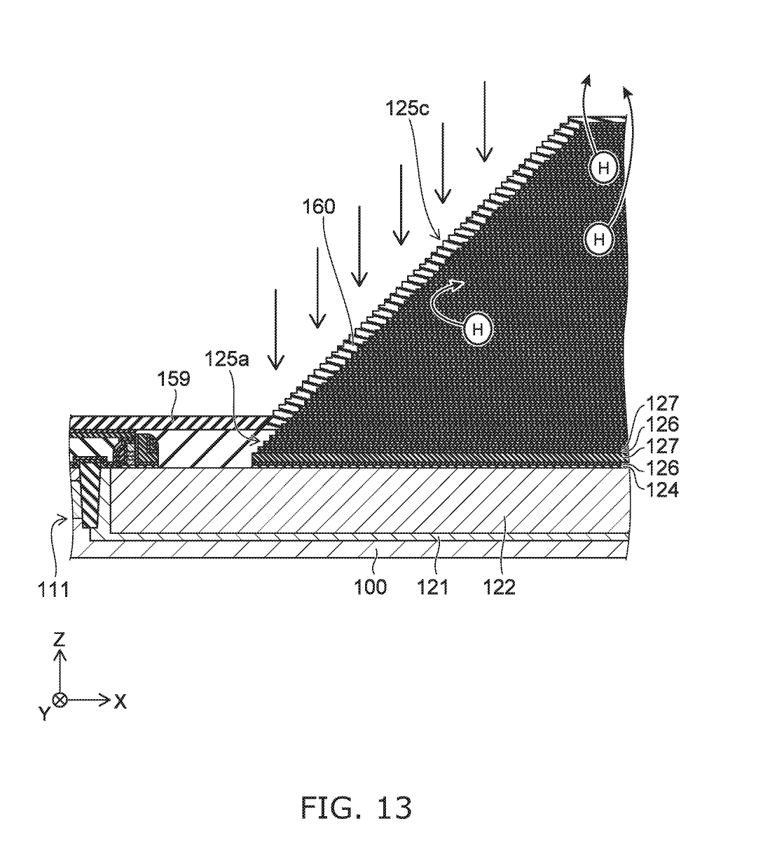

FIG. 13 is a sectional view showing a method for manufacturing a semiconductor memory device according to this embodiment.

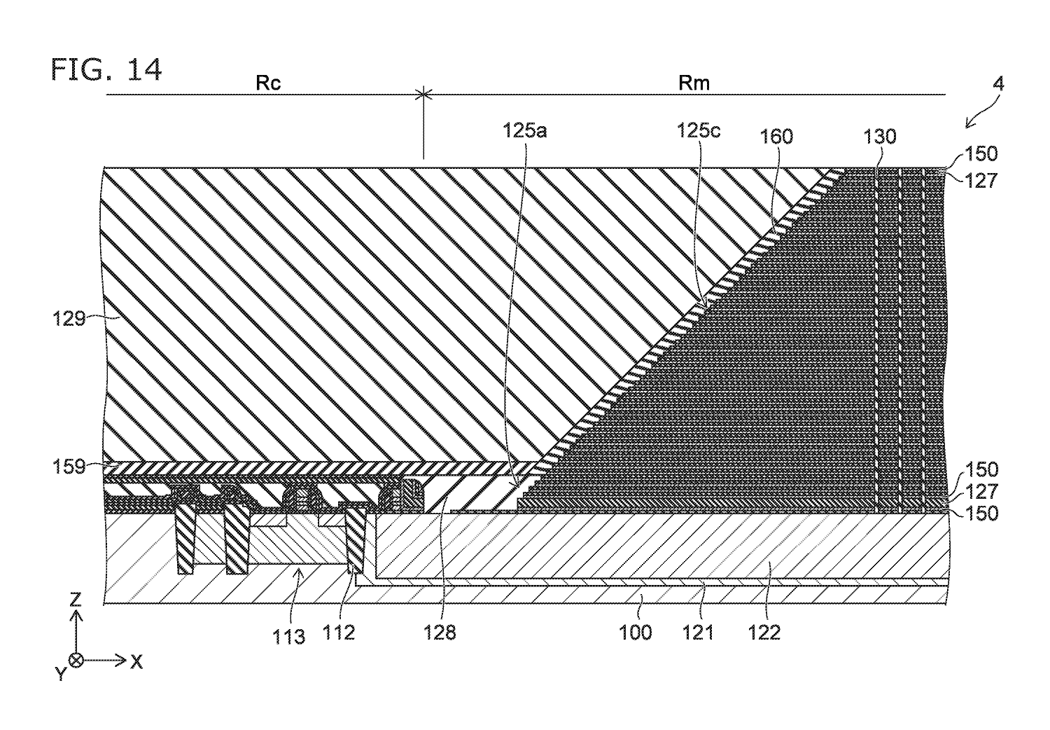

FIG. 14 is a sectional view showing the semiconductor memory device according to this embodiment.

As shown in FIG. 13, in this embodiment, a stacked body 125c is formed on the intermediate structural body 111. Then, a silicon oxide film 159 is formed on the entire surface. Next, the portion of the silicon oxide film 159 covering the end part of the stacked body 125c is ion-implanted with impurities such as phosphorus, arsenic, or boron. Thus, the portion of the silicon oxide film 159 covering the stacked body 125c is altered to a block film 160. Accordingly, the block film 160 contains PSG, BSG, or BPSG. Instead of forming a silicon oxide film 159 and performing ion implantation with impurities, the block film 160 may be formed by forming a film of PSG, BSG, or BPSG.

The silicon oxide film 159 thus provided blocks diffusion of hydrogen emitted from the stacked body 125c into the peripheral circuit region Rc, and the hydrogen is ejected upward. This can suppress that hydrogen emitted from the stacked body 125c damages the peripheral circuit region Rc.

Next, a process similar to the above first embodiment is performed. Thus, as shown in FIG. 14, the semiconductor memory device 4 according to this embodiment is manufactured. In the semiconductor memory device 4, the block film 160 is provided so as to cover the end part of the stacked body 125c.

The manufacturing method, configuration, and effect of this embodiment other than the foregoing are similar to those of the above first embodiment.

### Fifth Embodiment

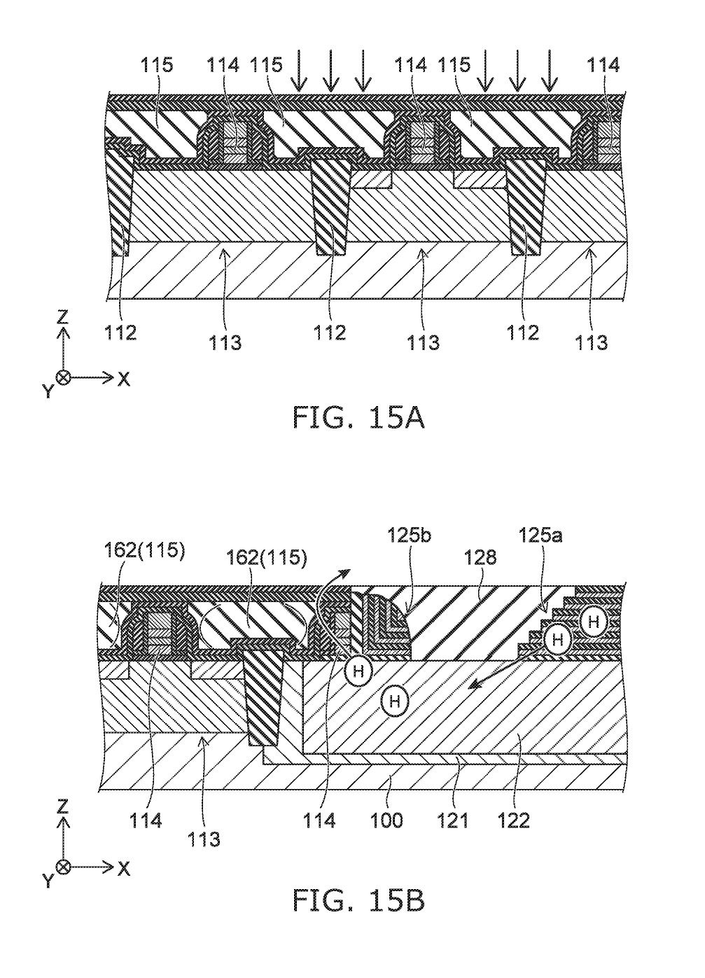

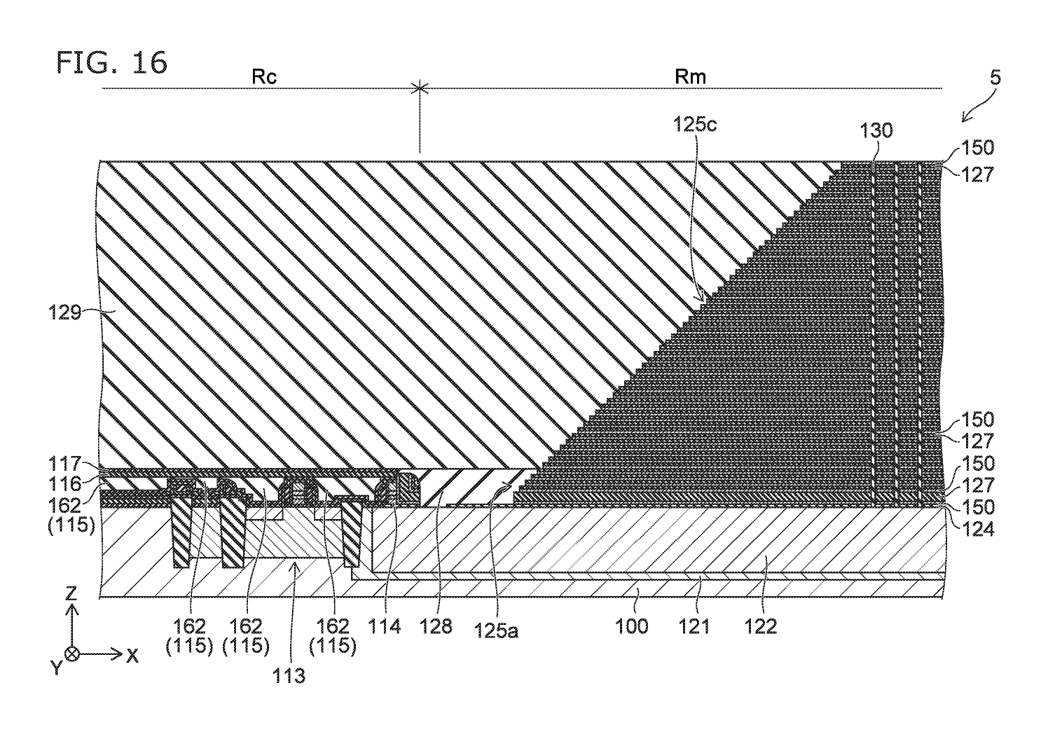

FIGS. 15A and 15B are sectional views showing a method for manufacturing a semiconductor memory device according to this embodiment.

FIG. 16 is a sectional view showing the semiconductor memory device according to this embodiment.

As shown in FIG. 15A, in this embodiment, when the intermediate structural body 111 is fabricated using a silicon substrate 100, a silicon oxide film 115 is formed between the gate electrodes 114 of the adjacent transistors 113 in the peripheral circuit region Rc. Then, this silicon oxide film 115 is ion-implanted with impurities such as phosphorus, arsenic, or boron.

Thus, as shown in FIG. 15B, the silicon oxide film 115 is turned to a block member 162 containing PSG, BSG, or BPSG. Accordingly, even if hydrogen diffuses in the silicon substrate 100 from the stacked body 125a and intrudes into the peripheral circuit region Rc, horizontal migration of the hydrogen is blocked by the block member 162, and the hydrogen is ejected upward.

Subsequently, as shown in FIG. 16, a process similar to the first embodiment is performed to manufacture a semiconductor memory device 5 according to this embodiment.

In the semiconductor memory device 5, the block member 162 is provided between the gate electrodes 114 of the adjacent transistors 113 provided in the peripheral circuit region Rc.

The manufacturing method, configuration, and effect of this embodiment other than the foregoing are similar to those of the above first embodiment.

### Sixth Embodiment

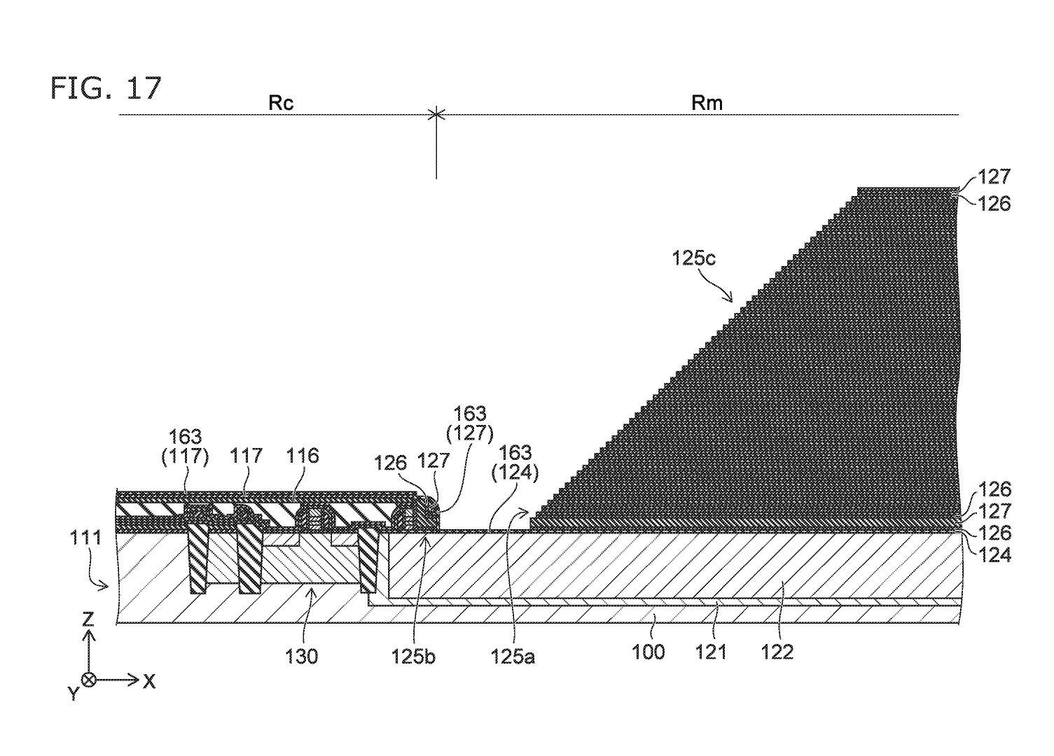

FIG. 17 is a sectional view showing a method for manufacturing a semiconductor memory device according to this embodiment.

As shown in FIG. 17, in this embodiment, the intermediate structural body 111 is fabricated, the stacked body 125c is formed, and the end part of the stacked body 125c is processed in a staircase shape.

Next, ion implantation is performed with impurities such as phosphorus, arsenic, or boron from above, i.e., Z-direction. Thus, the portion of the silicon oxide film 124 not covered with the stacked bodies 125a and 125b, the silicon oxide film 127 in the stacked body 125b, and the silicon oxide film 117 are doped with impurities and turned to a block film 163. In order to further increase the impurity concentration of the portion of the block film 163 formed at the surface of the stacked body 125b, impurities may be ion-implanted from a direction (oblique direction) inclined with respect to the Z-direction.

The manufacturing method, configuration, and effect of this embodiment other than the foregoing are similar to those of the above first embodiment.

### Seventh Embodiment

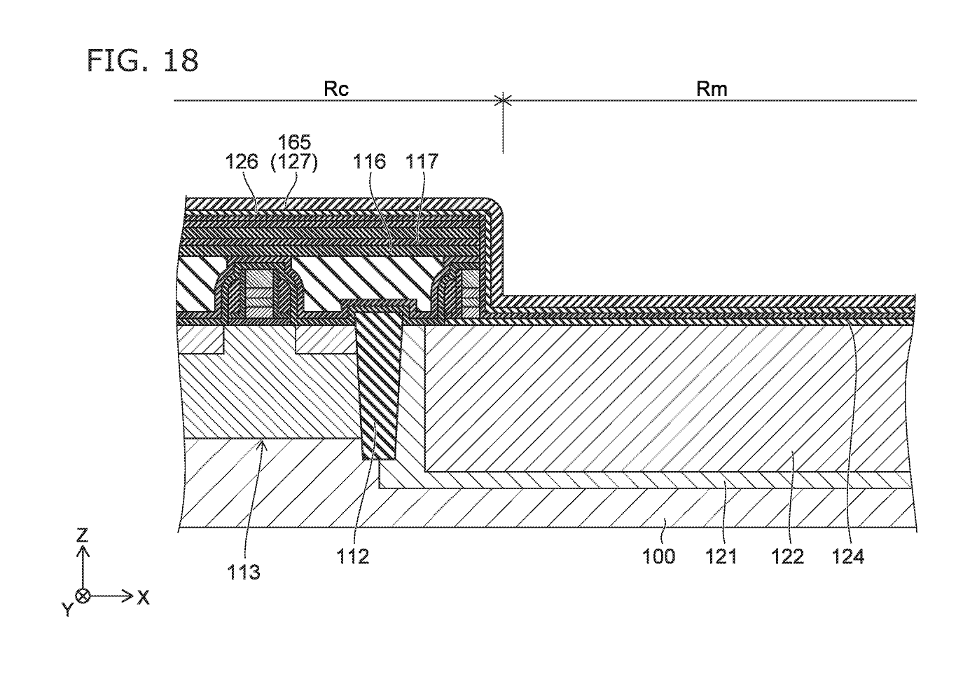

FIG. 18 is a sectional view showing a method for manufacturing a semiconductor memory device according to this embodiment.

As shown in FIG. 18, in this embodiment, an n-type well 121 and a p-type well 122 are formed in a silicon substrate 100. A silicon oxide film 124 is formed on the silicon substrate 100. A transistor 113 and the like are formed on the silicon substrate 100.

Next, a silicon nitride film 126 and a silicon oxide film 127 are formed, one layer each. This silicon nitride film 126 and this silicon oxide film 127 are divided in a later step and constitute a lowermost layer of the stacked bodies 125a and 125b.

Next, ion implantation is performed with impurities such as phosphorus, arsenic, or boron from above. Thus, the silicon oxide film 127 is doped with impurities and turned to a block film 165. At this time, in the silicon oxide film 127, the portion formed on the silicon oxide film 124 and the portion formed on the silicon oxide film 117 are doped with impurities. For this purpose, it is preferable to implant impurity ions from directly above (Z-direction). On the other hand, the portion of the silicon oxide film 127 formed on the side surface of the step difference of the boundary between the memory cell region Rm and the peripheral circuit region Rc is doped with impurities. For this purpose, it is preferable to implant impurities from a direction (oblique direction) crossing the Z-direction.

In the manufactured semiconductor memory device, the impurity concentration of the lowermost silicon oxide film 127 in the stacked body 125, e.g. the concentration of phosphorus, arsenic, or boron, is higher than the impurity concentration of one silicon oxide film 127 in an upper stage.

The manufacturing method, configuration, and effect of this embodiment other than the foregoing are similar to those of the above first embodiment.

### Eighth Embodiment

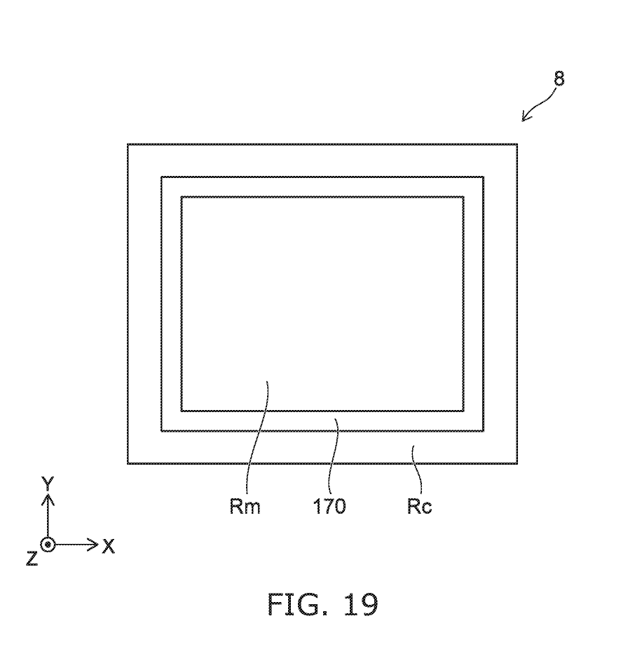

FIG. 19 is a plan view showing a semiconductor memory device according to this embodiment.

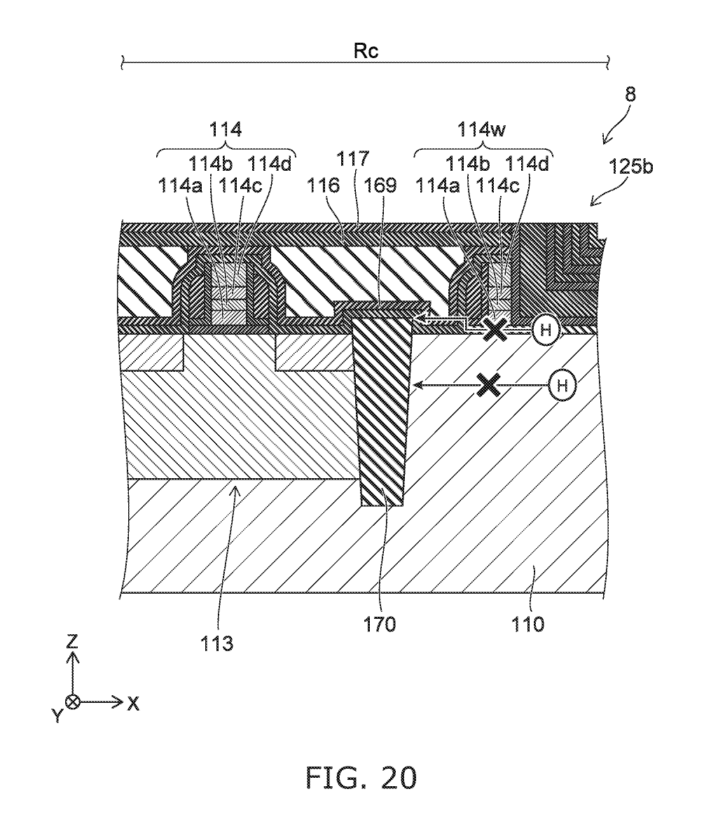

FIG. 20 is a sectional view showing the semiconductor memory device according to this embodiment.

As shown in FIG. 19, in the semiconductor memory device 8 according to this embodiment, STI 170 is provided between the memory cell region Rm and the peripheral circuit region Rc. As viewed in the Z-direction, the STI 170 is shaped like a frame surrounding the memory cell region Rm.

As shown in FIG. 20, the STI 170 is placed between the transistor 113 of the peripheral circuit region Rc nearest to the memory cell region Rm and the immediately underlying region of the dummy gate electrode structural body 114w provided on the memory cell region Rm side thereof. The configuration of the dummy gate electrode structural body 114w is the same as the configuration of the normal gate electrode 114w. However, the dummy gate electrode structural body 114w does not constitute a transistor 113 and does not function electrically.

The upper part of the STI 170 protrudes from the upper surface of the silicon substrate 100. The portion other than the upper part is placed in the silicon substrate 100. The STI 170 is formed from silicon nitride (SiN).

A liner film 169 made of silicon nitride is provided on the side surface of the gate electrode 114 of the transistor 113, on the side surface of the gate electrode structural body 114w, and on the region of the upper surface of the silicon substrate 100 between the gate electrode 114 and the gate electrode structural body 114w. The upper surface of the STI 170 is in contact with the lower surface of the liner film 169.

Silicon nitride has a lower diffusion coefficient of hydrogen than silicon oxide. Thus, the STI 170 functions as a block member for suppressing diffusion of hydrogen. Hence, according to this embodiment, migration of hydrogen between the memory cell region Rm and the peripheral circuit region Rc in the silicon substrate 100 can be suppressed by the STI 170. This can suppress that hydrogen emitted from the stacked body 125 (see FIG. 20) provided in the memory cell region Rm and diffused into the silicon substrate 100 migrates in the silicon substrate 100 and reaches the transistor 113.

Because the STI 170 is in contact with the liner film 169, the diffusion path of hydrogen can be blocked more reliably.

The manufacturing method, configuration, and effect of this embodiment other than the foregoing are similar to those of the above first embodiment.

The material of the STI 170 is not limited to silicon nitride, but only needs to be a material in which hydrogen diffuses less easily than in silicon oxide (SiO). For instance, it is possible to use e.g. silicon oxycarbide (SiOC), PSG, BSG, or BPSG.

### Ninth Embodiment

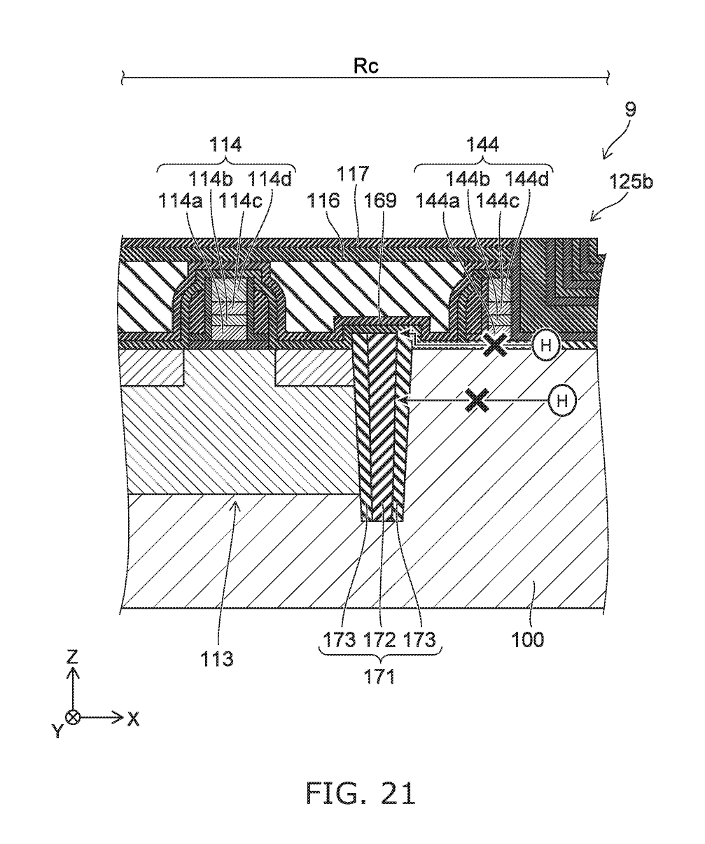

FIG. 21 is a sectional view showing a semiconductor memory device according to this embodiment.

As shown in FIG. 21, the semiconductor memory device 9 according to this embodiment is different from the semiconductor memory device 8 (see FIG. 20) according to the above eighth embodiment in that STI 171 is provided instead of the STI 170. The STI 171 is provided with a core member 172 made of silicon nitride and a spacer 173 provided on both side surfaces of the core member 172 and made of silicon oxide. That is, the core member 172 is placed between two spacers 173. The core member 172 and the spacer 173 each surround the memory cell region Rm. The thickness of the core member 172 is e.g. 100 nm or more.

According to this embodiment, the core member 172 made of silicon nitride is provided in the STI 171. This can suppress diffusion of hydrogen in the silicon substrate 100. Furthermore, the spacer 173 made of silicon oxide is provided on both side surfaces of the core member 172. This can suppress that the core member 172 made of silicon nitride affects the characteristics of the transistor 113.

Because the core member 172 is in contact with the liner film 169, the diffusion path of hydrogen can be blocked more reliably.

The manufacturing method, configuration, and effect of this embodiment other than the foregoing are similar to those of the above eighth embodiment.

### Tenth Embodiment

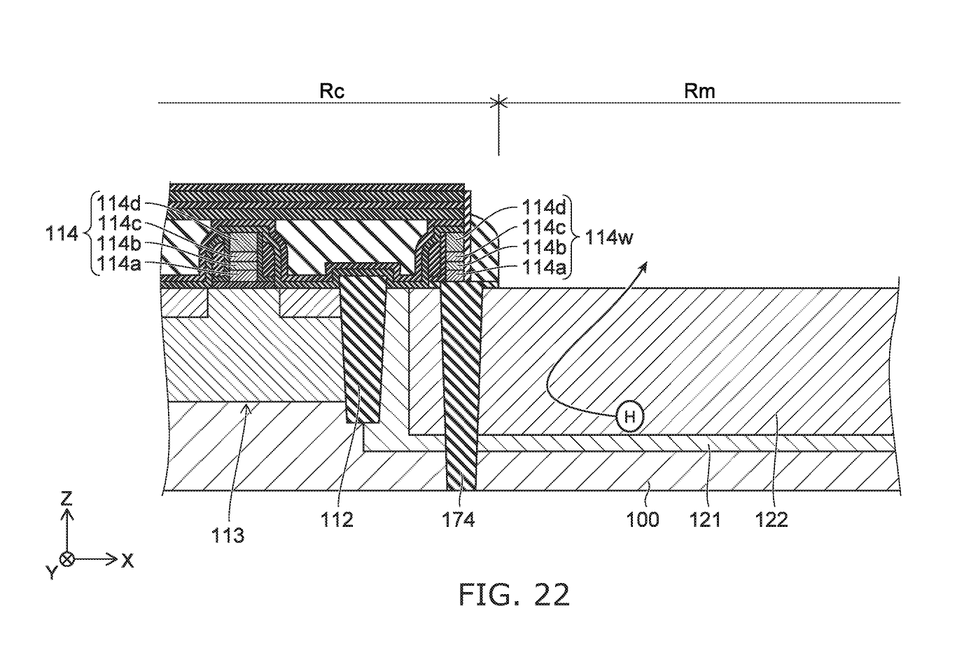

FIG. 22 is a sectional view showing a semiconductor memory device according to this embodiment.

As shown in FIG. 22, in this embodiment, STI 174 is provided immediately below the dummy gate electrode structural body 114w in the silicon substrate 100. As viewed in the Z-direction, the STI 174 surrounds the memory cell region Rm. The STI 174 is formed from a material such as silicon nitride, silicon oxycarbide, PSG, BSG, or BPSG in which hydrogen diffuses less easily than in silicon oxide (SiO).

This embodiment can also suppress diffusion of hydrogen between the memory cell region Rm and the peripheral circuit region Rc in the silicon substrate 100. Furthermore, the STI 174 is placed at a position remote from the transistor 113. This can suppress that the STI 174 affects the operation of the transistor 113.

The manufacturing method, configuration, and effect of this embodiment other than the foregoing are similar to those of the above ninth embodiment.

### Eleventh Embodiment

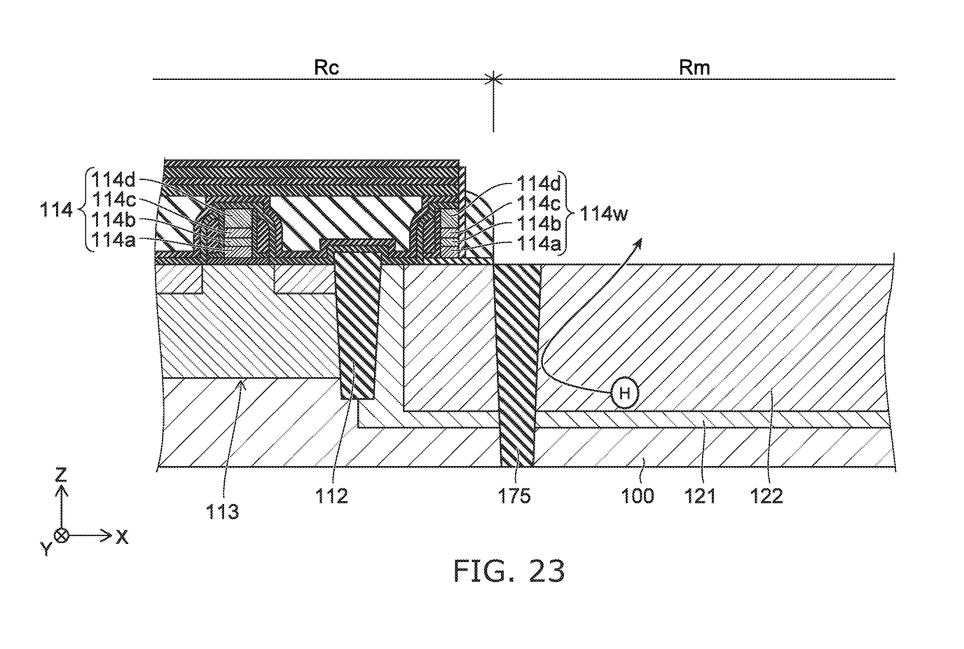

FIG. 23 is a sectional view showing a semiconductor memory device according to this embodiment.

As shown in FIG. 23, in this embodiment, STI 175 is provided on the memory cell region Rm side as viewed from the dummy gate electrode structural body 114w. That is, after the stacked body 125 is formed in the memory cell region Rm, the STI 175 is placed in the silicon substrate 100 between the immediately underlying region of the gate electrode structural body 114w and the immediately underlying region of the stacked body 125. As viewed in the Z-direction, the STI 175 surrounds the memory cell region Rm. The STI 175 is formed from a material such as silicon nitride, silicon oxycarbide, PSG, BSG, or BPSG in which hydrogen diffuses less easily than in silicon oxide (SiO).

This embodiment can also suppress diffusion of hydrogen between the memory cell region Rm and the peripheral circuit region Rc in the silicon substrate 100. Furthermore, the STI 175 is placed at a position more remote from the transistor 113. This can suppress more effectively that the STI 175 affects the operation of the transistor 113.

The manufacturing method, configuration, and effect of this embodiment other than the foregoing are similar to those of the above ninth embodiment.

### Twelfth Embodiment

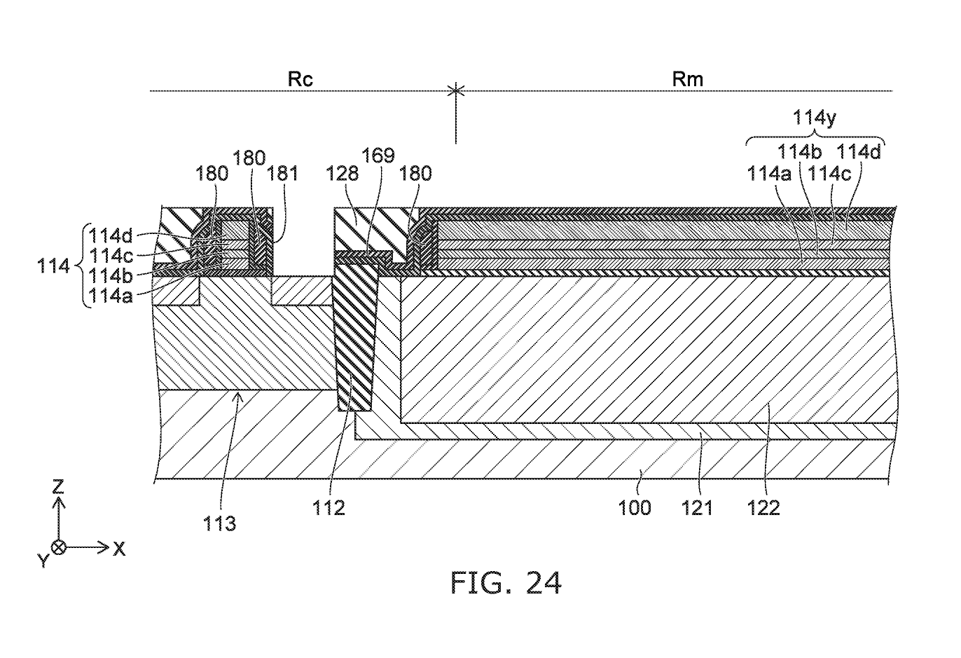

FIGS. 24 to 26 are sectional views showing a method for manufacturing a semiconductor memory device according to this embodiment.

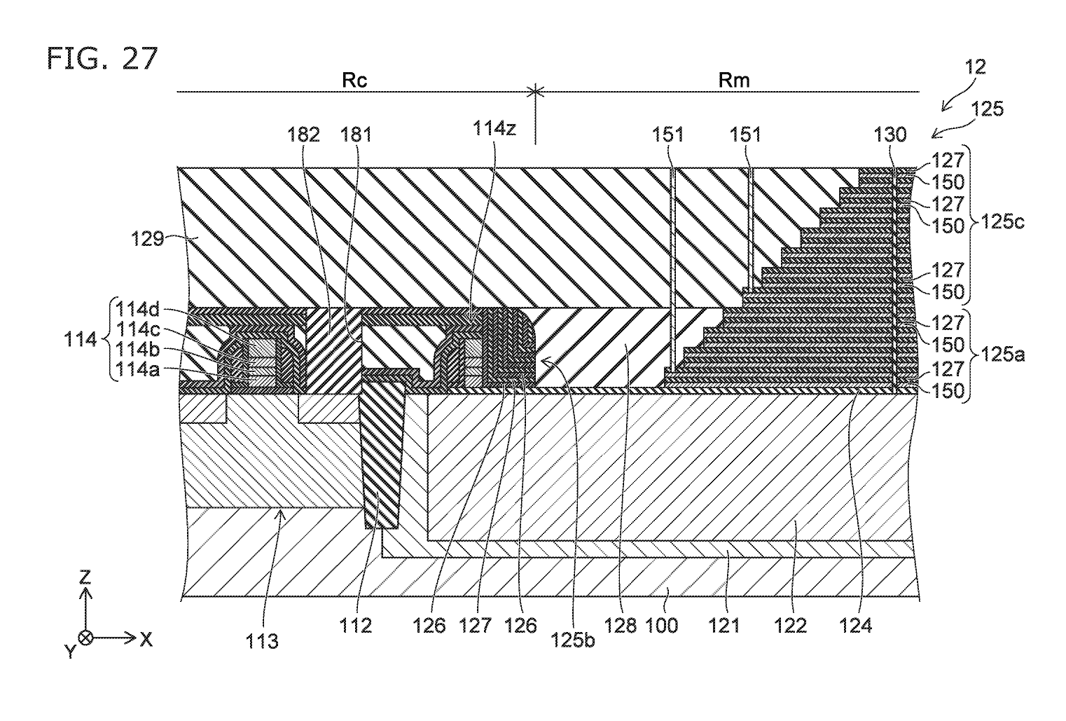

FIG. 27 is a sectional view showing the semiconductor memory device according to this embodiment.

First, as shown in FIG. 24, an n-type well 121 and a p-type well 122 are formed in a silicon substrate 100 in the memory cell region Rm. The diffusion layer of a transistor 113, STI 112 and the like are formed in the peripheral circuit region Rc.

Next, a polysilicon layer (Si layer) 114a, a tungsten silicide nitride layer (WSiN layer) 114b, a tungsten nitride layer (WN layer) 114c, and a tungsten layer (W layer) 114d are formed in this order on the entire surface to form a gate electrode film 114y. Next, the gate electrode film 114y is patterned to form a gate electrode 114 in the peripheral circuit region Rc. On the other hand, the gate electrode film 114y is left in the memory cell region Rm.

Next, a silicon oxide film is deposited, and RIE is performed. Thus, a sidewall 180 is formed on the side surface of the gate electrode 114 and on the side surface of the remaining portion of the gate electrode film 114y. Next, silicon nitride is deposited on the entire surface to form a liner film 169. Next, silicon oxide is deposited on the entire surface, and planarization processing such as CMP (chemical mechanical polishing) is performed. Thus, a silicon oxide film 128 is formed between the gate electrode 114 and the remaining portion of the gate electrode film 114y.

Next, a trench 181 is formed on the diffusion layer of the transistor 113 of the peripheral circuit region Rc located nearest to the memory cell region Rm. The trench 181 penetrates through the silicon oxide film 128 and the liner film 169 and reaches the silicon substrate 100.

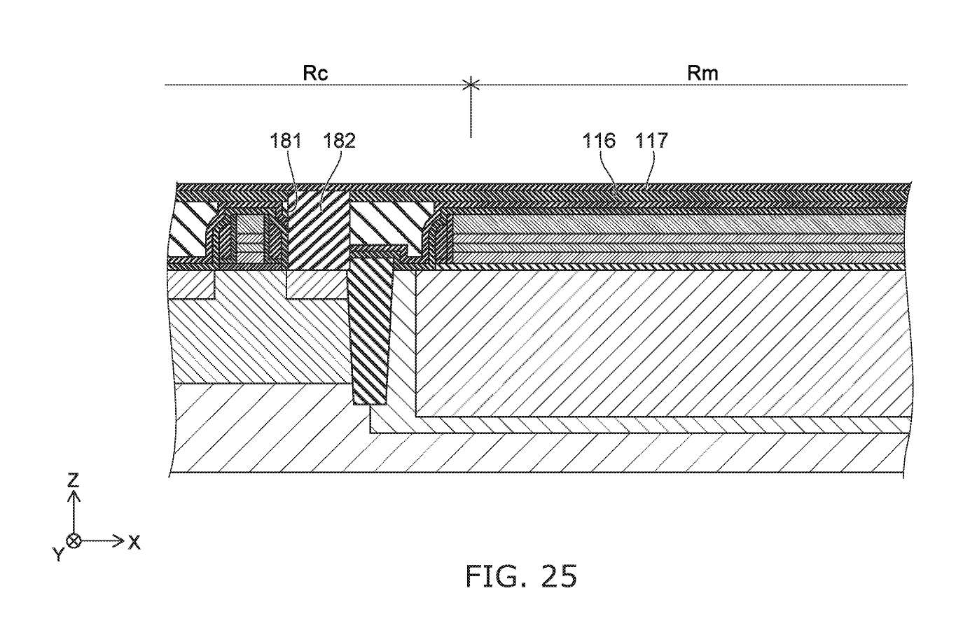

Next, as shown in FIG. 25, silicon nitride is deposited on the entire surface. Thus, a silicon nitride film 116 is formed on the entire surface, and a block member 182 is formed in the trench 181. Next, silicon oxide is deposited to form a silicon oxide film 117.

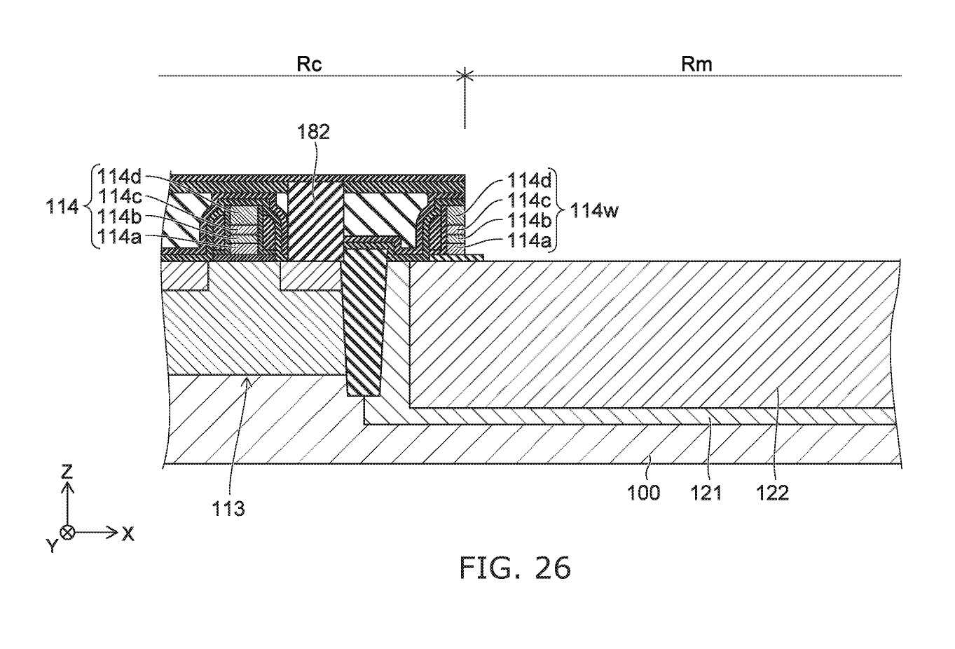

Next, as shown in FIG. 26, the gate electrode film 114y, the silicon nitride film 116, and the silicon oxide film 117 are removed in the memory cell region Rm. At this time, the gate electrode film 114y remaining in the end part of the peripheral circuit region Rc constitutes a gate electrode structural body 114w.

Next, as shown in FIG. 27, a process similar to the above first embodiment is performed. That is, silicon nitride films 126 and silicon oxide films 127 are stacked alternately and processed to form a stacked body 125a and a stacked body 125b. Next, a silicon oxide film 128 is buried between the stacked body 125a and the stacked body 125b. Next, silicon nitride films 126 and silicon oxide films 127 are stacked alternately and processed to form a stacked body 125c on the stacked body 125a.

Next, an interlayer insulating film 129 is formed so as to bury the stacked body 125 composed of the stacked bodies 125a and 125c. Next, a columnar member 130 is formed in the stacked body 125. Next, the silicon nitride film 126 of the stacked body 125 is replaced by an electrode film 150 through a slit (not shown). Next, a contact 151 is formed in the interlayer insulating film 129 and connected to the electrode film 150. Thus, the semiconductor memory device 12 according to this embodiment is manufactured.

In the semiconductor memory device 12 according to this embodiment, the block member 182 made of silicon nitride is provided in the end part on the memory cell region Rm side of the peripheral circuit region Rc. This can suppress that hydrogen emitted from the stacked body 125 reaches the transistor 113 of the peripheral circuit region Rc.

The manufacturing method, configuration, and effect of this embodiment other than the foregoing are similar to those of the above first embodiment.

### Thirteenth Embodiment

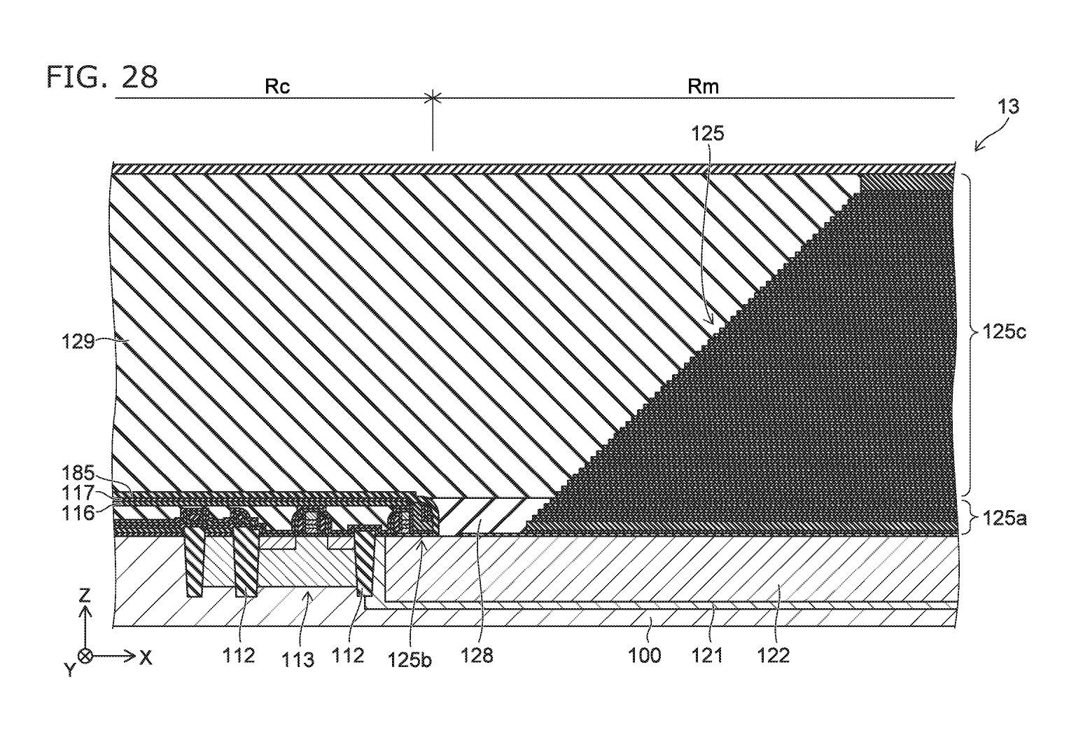

FIG. 28 is a sectional view showing a semiconductor memory device according to this embodiment.

As shown in FIG. 28, in the semiconductor memory device 13 according to this embodiment, in the peripheral circuit region Rc, an alumina film 185 made of aluminum oxide (e.g. Al₂O₃) is provided between the silicon oxide film 117 and the interlayer insulating film 129 and between the stacked body 125b and the silicon oxide film 128. The diffusion coefficient of hydrogen in aluminum oxide is lower than the diffusion coefficient of hydrogen in silicon oxide. Thus, the alumina film 185 functions as a block member for preventing diffusion of hydrogen.

The alumina film 185 is formed as follows. After the intermediate structural body 111 (see FIG. 1) is fabricated, aluminum oxide is deposited. Subsequently, the aluminum oxide is removed from the memory cell region Rm. Thus, the alumina film 185 is formed.

The manufacturing method, configuration, and effect of this embodiment other than the foregoing are similar to those of the above first embodiment.

### Fourteenth Embodiment

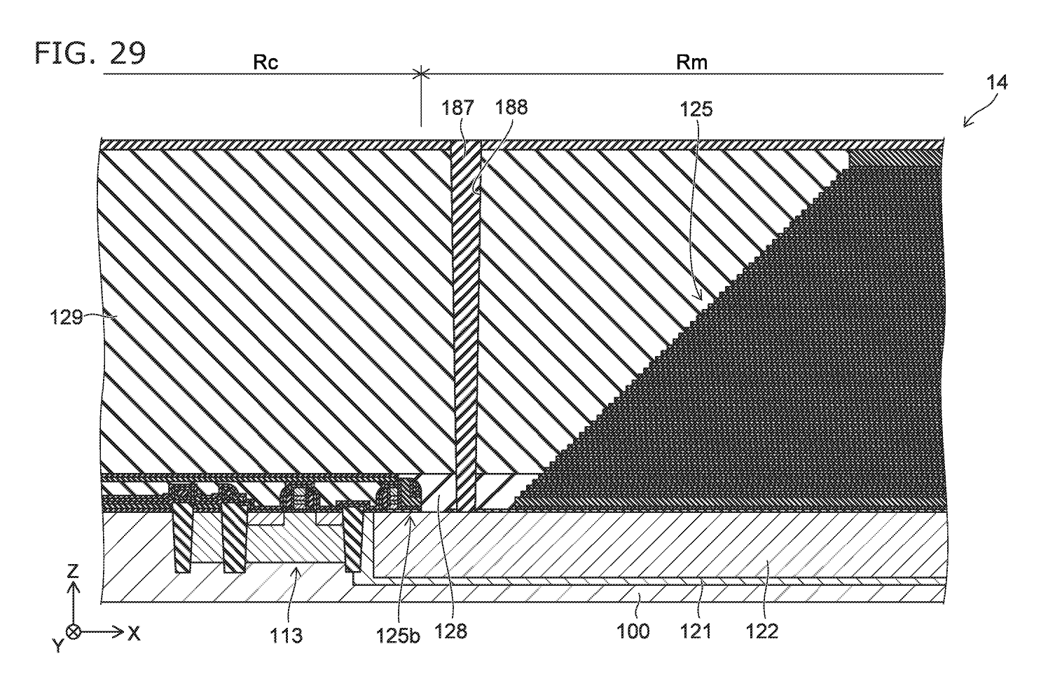

FIG. 29 is a sectional view showing a semiconductor memory device according to this embodiment.

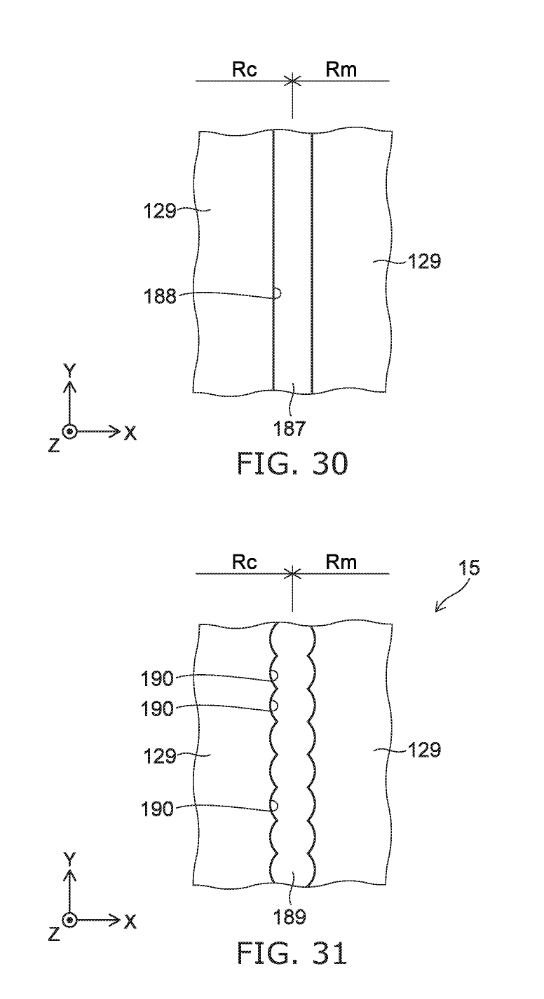

FIG. 30 is a plan view showing an alumina member of the semiconductor memory device according to this embodiment.

As shown in FIGS. 29 and 30, in the semiconductor memory device 14 according to this embodiment, an alumina member 187 shaped like a frame is provided so as to surround the memory cell region Rm. The alumina member 187 is formed from aluminum oxide (e.g. Al₂O₃). The alumina member 187 penetrates through the silicon oxide film 128 and the interlayer insulating film 129. The lower end of the alumina member 187 is in contact with the silicon substrate 100. As viewed in the Z-direction, the alumina member 187 is shaped like a rectangular frame along the outer edge of the memory cell region Rm. The portion corresponding to each side of the rectangle is shaped like a line. In this embodiment, the alumina member 187 functions as a block member for preventing diffusion of hydrogen.

The alumina member 187 is formed as follows. After the interlayer insulating film 129 is formed, a frame-shaped, line-shaped trench 188 is formed in the interlayer insulating film 129 and the silicon oxide film 128. Then, aluminum oxide is buried in the trench 188, and the aluminum oxide is removed from above the interlayer insulating film 129. Thus, the alumina member 187 is formed.

The manufacturing method, configuration, and effect of this embodiment other than the foregoing are similar to those of the above first embodiment.

### Fifteenth Embodiment

FIG. 31 is a plan view showing an alumina member of a semiconductor memory device according to this embodiment.

As shown in FIG. 31, an alumina member 189 is provided in the semiconductor memory device 15 according to this embodiment. As viewed in the Z-direction, the alumina member 189 is shaped like a rectangular frame along the outer edge of the memory cell region Rm and surrounds the memory cell region Rm. The portion of the alumina member 189 corresponding to each side of the rectangle is shaped like a plurality of circles connected in a line.

In this embodiment, the alumina member 189 is formed as follows. A plurality of holes 190 are formed in communication with each other in the interlayer insulating film 129 and the silicon oxide film 128. Then, aluminum oxide is buried in these holes 190. Thus, the alumina member 189 is formed. Accordingly, a through hole for burying the alumina member 189 can be formed in the same process as the hole pattern of the other portion. Thus, there is no need of a dedicated process for forming a through hole. This can suppress the increase of manufacturing cost associated with the formation of the alumina member 189.

The manufacturing method, configuration, and effect of this embodiment other than the foregoing are similar to those of the above fourteenth embodiment.

### (Sixteenth Embodiment

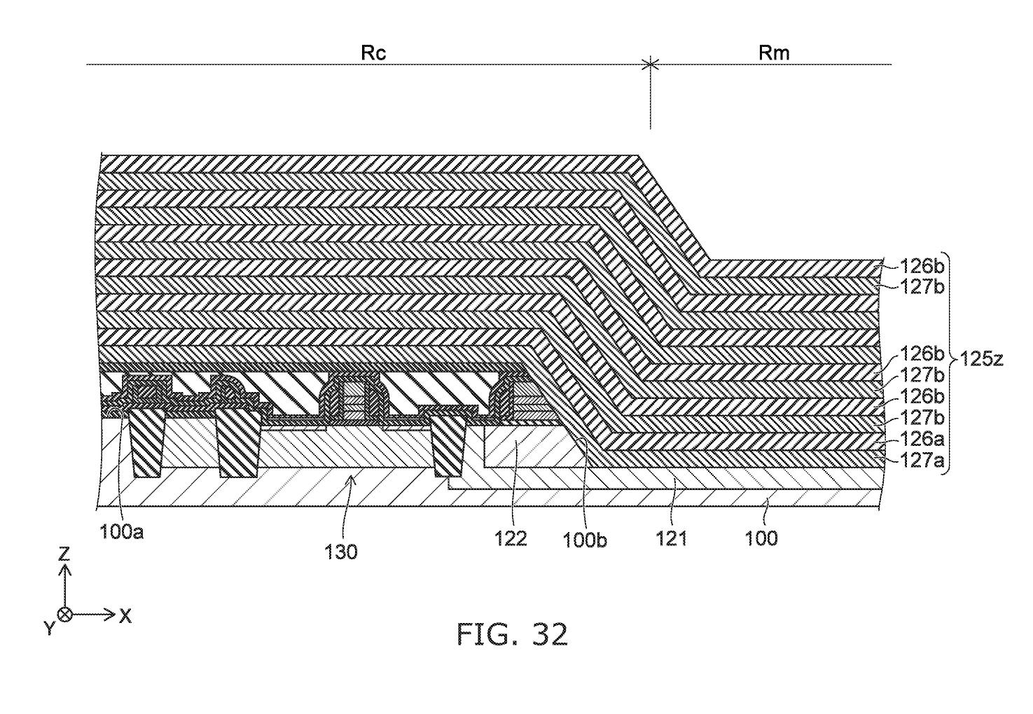

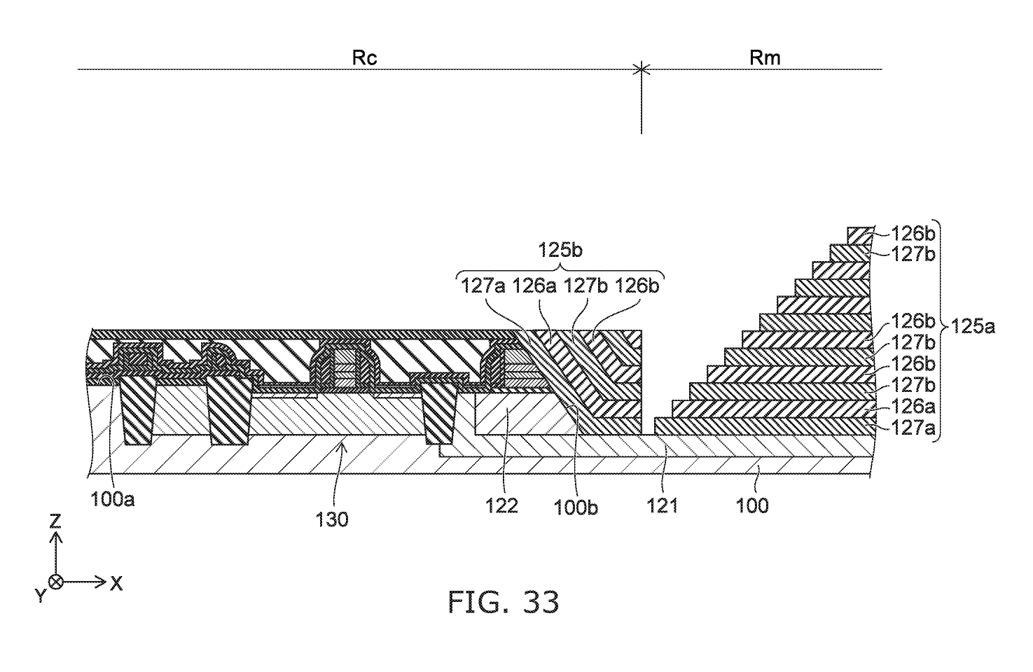

FIGS. 32 and 33 are sectional views showing a method for manufacturing a semiconductor memory device according to this embodiment.

First, as shown in FIG. 32, an n-type well 121 and a p-type well 122 are formed in a silicon substrate 100. A transistor 113 and the like are formed on the silicon substrate 100.

Next, the upper surface of the silicon substrate 100 is dug in the memory cell region Rm. At this time, the region including the boundary between the memory cell region Rm and the peripheral circuit region Rc is not shaped like a vertical surface, but a gradually inclined surface 100b. The inclination angle of the inclined surface 100b with respect to the upper surface 100a is set to e.g. 30-70°. The upper surface 100a is parallel to the XY plane.

Next, one or more silicon oxide films 127a and silicon nitride films 126a are alternately formed by the LP-CVD (low pressure chemical vapor deposition) method. Next, a plurality of silicon oxide films 127b and a plurality of silicon nitride films 126b are formed alternately layer by layer by the normal pressure CVD method. The silicon oxide films 127a, the silicon nitride films 126a, the silicon oxide films 127b, and the silicon nitride films 126b form a stacked film 125z.

The density of the silicon oxide film 127a is higher than the density of the silicon oxide film 127b. The density of the silicon nitride film 126a is higher than the density of the silicon nitride film 126b. The silicon oxide film 127a is made thicker than the silicon oxide film 127b. The silicon nitride film 126a is made thicker than the silicon nitride film 126b.

Next, as shown in FIG. 33, a resist pattern (not shown) is formed on the stacked film 125z. Etching using this resist pattern as a mask and slimming this resist pattern are alternately performed to partition a stacked body 125a from the stacked film 125z and to process the end part of the stacked film 125a in a staircase shape. At this time, a stacked body 125b is formed inevitably on the inclined surface 100b of the silicon substrate 100.

Next, a process similar to the above first embodiment is performed. Thus, the silicon nitride films 126a and 126b of the stacked body 125 are replaced by electrode films 150. On the other hand, the silicon nitride films 126a and 126b of the stacked body 125b remain without replacement. Each film of the stacked body 125b is bent. The stacking direction of the portion of the stacked body 125b placed on the memory cell region Rm side is the Z-direction. On the other hand, the stacking direction of the portion of the stacked body 125b placed on the peripheral circuit region Rc side is generally perpendicular to the inclined surface 100b and is a direction inclined with respect to the Z-direction.

According to this embodiment, the silicon oxide film 127a and the silicon nitride film 126a placed in the lower part of the stacked body 125 are formed by the LP-CVD method. The silicon oxide film 127b and the silicon nitride film 126b placed in the upper part of the stacked body 125 are formed by the normal pressure CVD method. Thus, the density of the silicon oxide film 127a is higher than the density of the silicon oxide film 127b. The density of the silicon nitride film 126a is higher than the density of the silicon nitride film 126b. The silicon oxide film 127a is thicker than the silicon oxide film 127b. The silicon nitride film 126a is thicker than the silicon nitride film 126b.

Thus, downward diffusion of hydrogen contained in the stacked body 125 is suppressed by the silicon oxide film 127a and the silicon nitride film 126a. Accordingly, the hydrogen is released upward. This can suppress that hydrogen contained in the stacked body 125 diffuses in the silicon substrate 100 and intrudes into the peripheral circuit region Rc.

The manufacturing method, configuration, and effect of this embodiment other than the foregoing are similar to those of the above first embodiment.

The embodiments described above can realize a semiconductor memory device having high reliability and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device comprising:
a substrate; and
a stacked body provided on the substrate, a plurality of silicon oxide films and a plurality of electrode films being stacked alternately one by one in the stacked body, and an end part of the stacked body being shaped like a staircase in which a terrace is formed for each of the plurality of electrode films,
a lowermost one of the plurality of electrode films being continuously thinned toward a tip.

2. The device according to claim 1, wherein curvature of the tip of the lowermost electrode film is larger than curvature of a tip of an uppermost one of the plurality of electrode films.

3. The device according to claim 1, further comprising:
a semiconductor pillar provided in the stacked body and extending in a stacking direction of the plurality of silicon oxide films and the plurality of electrode films; and
a charge storage member provided between one of the plurality of electrode films and the semiconductor pillar.

4. A semiconductor memory device comprising:
a substrate;
a first stacked body provided in a first region on the substrate, a plurality of first silicon oxide films and a plurality of electrode films being stacked alternately one by one in the first stacked body;
a transistor formed in a second region of the substrate; and
a block member provided between the first stacked body and the transistor, diffusion coefficient of hydrogen in the block member being lower than diffusion coefficient of hydrogen in silicon oxide.

5. The device according to claim 4, wherein the block member contains one or more elements selected from the group consisting of phosphorus, arsenic, and boron, silicon, and oxygen.

6. The device according to claim 4, wherein the block member contains silicon and nitrogen.

7. The device according to claim 4, wherein the block member contains aluminum and oxygen.

8. The device according to claim 4, wherein
an end part of the first stacked body directed to the second region is shaped like a staircase in which a terrace is formed for each of the plurality of electrode films, and
the block member is placed on the terrace provided in a lowermost stage of the first stacked body.

9. The device according to claim 4, further comprising:
a second stacked body provided between the first stacked body and the transistor, a plurality of second silicon oxide films and a plurality of silicon nitride films being stacked one by one in the second stacked body; and
a third silicon oxide film provided between the first stacked body and the second stacked body,
wherein the block member is placed in the third silicon oxide film.

10. The device according to claim 4, wherein
an end part of the first stacked body directed to the second region is shaped like a staircase in which a terrace is formed for each of the plurality of electrode films, and
the block member covers part of the end part of the first stacked body.

11. The device according to claim 4, wherein
the transistor is provided in a plurality in the second region, and
the block member is placed between gate electrodes of the adjacent transistors.

12. The device according to claim 4, wherein the block member is placed on the transistor.

13. The device according to claim 4, wherein an upper part of the block member protrudes from an upper surface of the substrate, and a portion of the block member except the upper part is placed in the substrate.

14. The device according to claim 13, wherein
the second region surrounds the first region, and
the block member surrounds the first region.

15. The device according to claim 13, further comprising:
a gate electrode structural body provided on the substrate in the second region and not constituting a transistor,
wherein the block member is placed between an immediately underlying region of a gate electrode of the transistor and an immediately underlying region of the gate electrode structural body.

16. The device according to claim 13, wherein the block member is made of silicon nitride.

17. The device according to claim 13, wherein the block member includes:
a core member made of silicon nitride; and
a spacer provided on both side surfaces of the core member and made of silicon oxide.

18. The device according to claim 13, further comprising:
a gate electrode structural body provided on the substrate in the second region and not constituting a transistor,
wherein the block member is placed immediately below the gate electrode structural body.

19. The device according to claim 13, further comprising:
a gate electrode structural body provided on the substrate in the second region and not constituting a transistor,
wherein the block member is placed between an immediately underlying region of the gate electrode structural body and an immediately underlying region of the first stacked body.

20. The device according to claim 4, wherein the block member is placed immediately above a diffusion layer on the first region side of the transistor.

21. The device according to claim 4, further comprising:
a second stacked body provided between the first stacked body and the transistor, a plurality of second silicon oxide films and a plurality of silicon nitride films being stacked one by one in the second stacked body;
a third silicon oxide film provided between the first stacked body and the second stacked body; and
an interlayer insulating film provided on the first stacked body, on the third silicon oxide film, and on the transistor,
wherein the block member contains aluminum oxide and is placed between the transistor and the interlayer insulating film and between the second stacked body and the third silicon oxide film.

22. The device according to claim 4, further comprising:
a second stacked body provided between the first stacked body and the transistor, a plurality of second silicon oxide films and a plurality of silicon nitride films being stacked one by one in the second stacked body;
a third silicon oxide film provided between the first stacked body and the second stacked body; and
an interlayer insulating film provided on the first stacked body, on the third silicon oxide film, and on the transistor,
wherein the second region surrounds the first region, and
the block member contains aluminum oxide, is placed in the third silicon oxide film and in the interlayer insulating film, and surrounds the first stacked body.

23. The device according to claim 4, further comprising:
a semiconductor pillar provided in the first stacked body and extending in a stacking direction of the plurality of silicon oxide films and the plurality of electrode films; and
a charge storage member provided between one of the plurality of electrode films and the semiconductor pillar.

24. A semiconductor memory device comprising:
a substrate; and
a stacked body provided in a first region on the substrate, a plurality of silicon oxide films and a plurality of electrode films being stacked alternately one by one in the stacked body,
impurity concentration of a lowermost one of the silicon oxide films in the stacked body being higher than impurity concentration of a different one of the silicon oxide films.

25. A semiconductor memory device comprising:
a substrate, an upper surface of a first region being lower than an upper surface of a second region, and a region including a boundary between the first region and the second region being an inclined surface;
a first stacked body provided on the first region, a plurality of first silicon oxide films and a plurality of electrode films being stacked alternately one by one in the first stacked body; and
a second stacked body provided on the inclined surface, a plurality of second silicon oxide films and a plurality of electrode films being stacked alternately one by one in the second stacked body,
density of a lowermost one of the first silicon oxide films of the first stacked body being higher than density of an uppermost one of the first silicon oxide films of the first stacked body.

26. A semiconductor memory device comprising:
a substrate, an upper surface of a first region being lower than an upper surface of a second region, and a region including a boundary between the first region and the second region being an inclined surface;
a first stacked body provided on the first region, a plurality of first silicon oxide films and a plurality of electrode films being stacked alternately one by one in the first stacked body; and
a second stacked body provided on the inclined surface, a plurality of second silicon oxide films and a plurality of electrode films being stacked alternately one by one in the second stacked body,
a lowermost one of the first silicon oxide films of the first stacked body being thicker than an uppermost one of the first silicon oxide films of the first stacked body.

27. A method for manufacturing a semiconductor memory device, comprising:
forming a stacked body on a substrate by alternately forming silicon oxide films and silicon nitride films by a chemical vapor deposition method using a raw material gas containing hydrogen;
heating the stacked body; and
replacing the silicon nitride films by electrode films.

28. The method according to claim 27, wherein the heating the stacked body is performed in an oxidizing atmosphere.

29. A method for manufacturing a semiconductor memory device, comprising:
digging a first region of a substrate so that an end part is shaped like an inclined surface;
forming a first stacked film on the substrate by alternately forming first silicon oxide films and first silicon nitride films by a low pressure chemical vapor deposition method;
forming a second stacked film on the first stacked film by alternately forming second silicon oxide films and second silicon nitride films by a normal pressure chemical vapor deposition method;
etching the second stacked film and the first stacked film to process an end part of the first stacked film and the second stacked film in a staircase shape in which a terrace is formed for each of the first silicon nitride films and each of the second silicon nitride films; and
replacing the first silicon nitride films and the second silicon nitride films by electrode films.
